(19) United States
(12) Patent Application Publication
(10) Pub. No.: US 2026/0010270 A1
(43) Pub. Date: Jan. 8, 2026

(54) ELECTRONIC DEVICE

(71) Applicant: Samsung Display Co., Ltd., Yongin-si (KR)

(72) Inventors: JEONGYUN HAN, Yongin-si (KR); GYEONGNAM BANG, Yongin-si (KR); HWAN-HEE JEONG, Yongin-si (KR)

(21) Appl. No.: 19/212,506

(22) Filed: May 19, 2025

(30) Foreign Application Priority Data
Jul. 3, 2024 (KR) 10-2024-0087393
Aug. 19, 2024 (KR) 10-2024-0110444

(51) Int. Cl. G06F 3/044; G06F 3/041; H10K 59/40

(52) U.S. Cl. CPC G06F 3/0446; G06F 3/0412; G06F 3/04164; G06F 3/0443; G06F 3/0448; G06F 2203/04106; G06F 2203/04112; H10K 59/40

(57) ABSTRACT

An electronic device includes: a display layer including a display area to display an image, and a non-display area adjacent to the display area; and a sensor layer on the display layer, and including: a plurality of first electrodes along a first direction; a plurality of second electrodes along a second direction crossing the first direction; a plurality of third electrodes along the first direction, and overlapping with the plurality of first electrodes; and a plurality of fourth electrodes along the second direction, and overlapping with the plurality of second electrodes. At least a part of the plurality of first electrodes, the plurality of second electrodes, the plurality of third electrodes, and the plurality of fourth electrodes overlaps with the non-display area.

### CROSS-REFERENCE TO RELATED APPLICATIONS

The present application claims priority to and the benefit of Korean Patent Application No. 10-2024-0087393, filed on Jul. 3, 2024, and Korean Patent Application No. 10-2024-0110444, filed on Aug. 19, 2024, in the Korean Intellectual Property Office, the entire disclosures of all of which are incorporated by reference herein.

### BACKGROUND

Aspects of embodiments of the present disclosure relate to an electronic device having an increased sensing area.

A multimedia electronic device, such as a television (TV), a mobile phone, a tablet computer, a notebook, a navigation system, or a game console, includes a display device for displaying an image. In addition to a general input method, such as a button, a keyboard, a mouse, or the like, the electronic device may include a sensor layer (e.g., an input sensor) capable of providing a touch-based input method that allows a user to enter information or commands more easily and intuitively. The sensor layer may sense a user's touch or pressure. Recently, there is an increasing demand for using a pen for a finer touch input for a user who may be accustomed to entering information by using writing instruments, or for a specific application (e.g., an application program for sketching or drawing).

The above information disclosed in this Background section is for enhancement of understanding of the background of the present disclosure, and therefore, it may contain information that does not constitute prior art.

### SUMMARY

Embodiments of the present disclosure may be directed to an electronic device having a sensing area in which an area thereof may be increased, and in which a sensing accuracy in the outskirt of a display area thereof may be improved.

According to one or more embodiments of the present disclosure, an electronic device includes: a display layer including a display area configured to display an image, and a non-display area adjacent to the display area; and a sensor layer on the display layer, and including: a plurality of first electrodes along a first direction; a plurality of second electrodes along a second direction crossing the first direction; a plurality of third electrodes along the first direction, and overlapping with the plurality of first electrodes; and a plurality of fourth electrodes along the second direction, and overlapping with the plurality of second electrodes. At least a part of the plurality of first electrodes, the plurality of second electrodes, the plurality of third electrodes, and the plurality of fourth electrodes overlaps with the non-display area.

In an embodiment, a length of each of the plurality of first electrodes in the second direction may be larger than a width of the display area in the second direction.

In an embodiment, each of the plurality of first electrodes may include a first edge aligned with a boundary between the display area and the non-display area, and a second edge spaced from the first edge in the second direction.

In an embodiment, the electronic device may further include a plurality of pads electrically connected to the plurality of first electrodes, the plurality of second electrodes, the plurality of third electrodes, and the plurality of fourth electrodes. The first edge may be located between the plurality of pads and the second edge.

In an embodiment, at least a part of the plurality of first electrodes, the plurality of second electrodes, the plurality of third electrodes, and the plurality of fourth electrodes may include an extended portion overlapping with the non-display area, and a plurality of openings may be defined in the extended portion.

In an embodiment, each of the plurality of openings may have a circular shape.

In an embodiment, the plurality of first electrodes may include a plurality of first type electrodes in an area overlapping with the display area, and a second type electrode in an area overlapping with the non-display area.

In an embodiment, each of the plurality of first type electrodes may have a mesh structure in which a plurality of openings are defined, and the second type electrode may have a solid structure in which no opening is defined.

In an embodiment, the second type electrode may have a loop shape.

In an embodiment, the sensor layer may further include: a first loop trace line electrically connected to the plurality of third electrodes; and a plurality of second loop trace lines electrically connected to the plurality of third electrodes. The second type electrode may be adjacent to the first loop trace line.

In an embodiment, the first loop trace line may be located between the second type electrode and the display layer.

In an embodiment, one of the first loop trace line or the second type electrode may include: a first conductive line; and a second conductive line at a different layer from that of the first conductive line, and electrically connected to the first conductive line.

In an embodiment, the plurality of second electrodes may include a plurality of first type electrodes in an area overlapping with the display area, and a second type electrode in an area overlapping with the non-display area.

In an embodiment, the sensor layer may further include: a trace line electrically connected to the plurality of fourth electrodes; an auxiliary electrode electrically connected to the trace line, and overlapping with the non-display area; and an auxiliary trace line electrically connected to the second type electrode, and spaced from the trace line with the display area therebetween.

In an embodiment, the electronic device may further include a sensor driver configured to drive the sensor layer, and selectively operate in a first mode for sensing a touch input and a second mode for sensing a pen input. The second mode may include a charging driving mode and a pen sensing driving mode. In the charging driving mode, the sensor driver may be configured to provide a first signal to at least one third electrode among the plurality of third electrodes, and provide a second signal to at least another third electrode among the plurality of third electrodes. In the pen sensing driving mode, the sensor driver may be configured to receive first reception signals from the plurality of first electrodes, and receive second reception signals from the plurality of second electrodes.

According to one or more embodiments of the present disclosure, an electronic device includes: a display layer including a display area configured to display an image, and a non-display area adjacent to the display area; and a sensor layer on the display layer, and including: a plurality of first electrodes along a first direction; a plurality of second electrodes along a second direction crossing the first direction; a plurality of third electrodes along the first direction, and overlapping with the plurality of first electrodes; and a plurality of fourth electrodes along the second direction, and overlapping with the plurality of second electrodes, at least a part of the plurality of fourth electrodes being electrically connected to each other. At least a part of the plurality of first electrodes, the plurality of second electrodes, the plurality of third electrodes, and the plurality of fourth electrodes includes an extended portion overlapping with the non-display area, and a plurality of openings are defined in the extended portion.

According to one or more embodiments of the present disclosure, an electronic device includes: a display layer including a display area configured to display an image, and a non-display area adjacent to the display area; and a sensor layer on the display layer, and including: a plurality of first electrodes along a first direction; and a plurality of second electrodes along a second direction crossing the first direction. The plurality of first electrodes includes: a plurality of first type electrodes in an area overlapping with the display area; and a second type electrode in an area overlapping with the non-display area. Each of the plurality of first type electrodes has a mesh structure in which a plurality of openings are defined, and the second type electrode has a solid structure in which no opening is defined.

In an embodiment, the electronic device may further include: a first pad connected to one end of the second type electrode; and a second pad connected to another end of the second type electrode.

In an embodiment, the plurality of second electrodes may include: a plurality of third type electrodes in an area overlapping with the display area; and a fourth type electrode in an area overlapping with the non-display area.

In an embodiment, the sensor layer may further include: a plurality of third electrodes along the second direction, and overlapping with the plurality of second electrodes; a trace line electrically connected to the plurality of third electrodes; an auxiliary electrode electrically connected to the trace line, and overlapping with the non-display area; and an auxiliary trace line electrically connected to the fourth type electrode, and spaced from the trace line with the display area therebetween.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1A is a perspective view of an electronic device according to an embodiment of the present disclosure.

FIG. 1B is a rear perspective view of an electronic device according to an embodiment of the present disclosure.

FIG. 2 is a perspective view of an electronic device according to an embodiment of the present disclosure.

FIG. 3 is a perspective view of an electronic device according to an embodiment of the present disclosure.

FIG. 4 is a schematic cross-sectional view of a display panel according to an embodiment of the present disclosure.

FIG. 5 is a diagram illustrating an operation of an electronic device according to an embodiment of the present disclosure.

FIG. 6A is a cross-sectional view of a display panel according to an embodiment of the present disclosure.

FIG. 6B is a cross-sectional view illustrating a partial configuration of a sensor layer according to an embodiment of the present disclosure.

FIG. 7 is a plan view of a sensor layer according to an embodiment of the present disclosure.

FIG. 8A is a plan view illustrating a first conductive layer of a sensing unit according to an embodiment of the present disclosure.

FIG. 8B is a plan view illustrating a second conductive layer of a sensing unit according to an embodiment of the present disclosure.

FIG. 9 is an enlarged plan view of the region AA′ shown in FIG. 8B.

FIG. 10A is a plan view illustrating a sensing area and a display area according to an embodiment of the present disclosure.

FIG. 10B is a plan view illustrating a sensing area and a display area according to an embodiment of the present disclosure.

FIG. 10C is a plan view illustrating a sensing area and a display area according to an embodiment of the present disclosure.

FIG. 11 is a plan view showing a first conductive layer of a sensing unit arranged in the region BB′ illustrated in FIG. 10A.

FIG. 12A is a plan view showing a first conductive layer of a sensing unit arranged in the region CC′ illustrated in FIG. 10B.

FIG. 12B is a plan view showing a portion of a second conductive layer arranged in the region CC′ illustrated in FIG. 10B.

FIG. 13 is a plan view of a sensor layer according to an embodiment of the present disclosure.

FIG. 14 is a cross-sectional view of a display panel including a portion taken along the line I-I′ illustrated in FIG. 13 according to an embodiment of the present disclosure.

FIG. 15 is a cross-sectional view of a display panel including a portion taken along the line I-I′ illustrated in FIG. 13 according to an embodiment of the present disclosure.

FIG. 16 is a cross-sectional view of a display panel including a portion taken along the line I-I′ illustrated in FIG. 13 according to an embodiment of the present disclosure.

FIG. 17 is a plan view of a sensor layer according to an embodiment of the present disclosure.

FIG. 18 is a plan view of a sensor layer according to an embodiment of the present disclosure.

FIG. 19 is a diagram illustrating an operation of a sensor driver according to an embodiment of the present disclosure.

FIG. 20 is a diagram illustrating an operation of a sensor driver according to an embodiment of the present disclosure.

FIG. 21 is a diagram illustrating a first mode according to an embodiment of the present disclosure.

FIG. 22 is a diagram illustrating a second mode according to an embodiment of the present disclosure.

FIG. 23A is a graph showing a waveform of a first signal according to an embodiment of the present disclosure.

FIG. 23B is a graph showing a waveform of a second signal according to an embodiment of the present disclosure.

FIG. 24A is a diagram illustrating a second mode according to an embodiment of the present disclosure.

FIG. 24B is a diagram illustrating a second mode based on one sensing unit according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Hereinafter, the terms “part” and “unit” may refer to a software component or a hardware component that performs a specific function. The hardware component may include, for example, a field-programmable gate array (FPGA) or an application-specific integrated circuit (ASIC). The software component may refer to executable code and/or data used by the executable code in an addressable storage medium. Thus, software components may be, for example, object-oriented software components, class components, and task components, and may include processes, functions, properties, procedures, subroutines, program code segments, drivers, firmware, microcode, circuits, data, database, data structures, tables, arrays, or variables.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

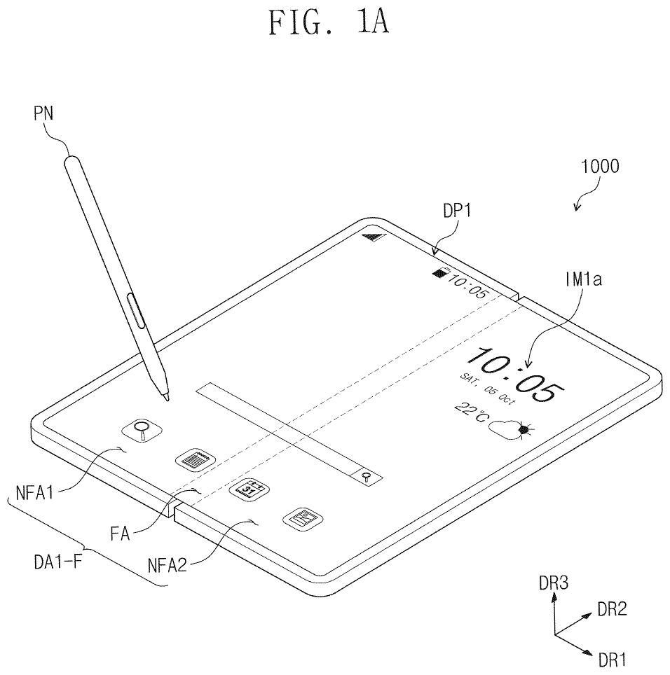

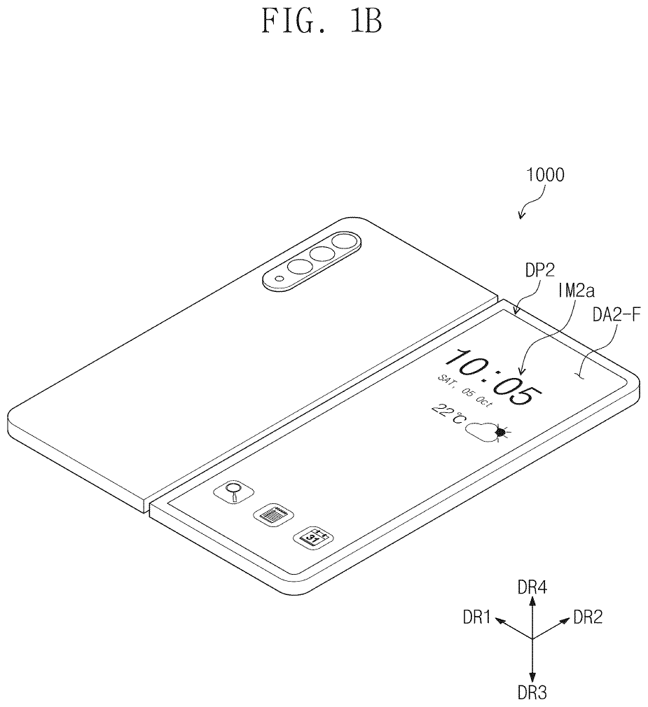

FIG. 1A is a perspective view of an electronic device 1000 according to an embodiment of the present disclosure. FIG. 1B is a rear perspective view of the electronic device 1000 according to an embodiment of the present disclosure.

Referring to FIGS. 1A and 1B, the electronic device 1000 may refer to a device that is activated depending on an electrical signal. For example, the electronic device 1000 may display an image, and may sense external inputs applied from the outside. The external input may be an input of the user. The input of the user may include various suitable kinds of external inputs, such as a part of a user's body, a pen PN, light, heat, and/or pressure.

The electronic device 1000 may include a first display panel DP1 and a second display panel DP2. The first display panel DP1 and the second display panel DP2 may be independent panels that are separated from each other. The first display panel DP1 may be referred to as a “main display panel”. The second display panel DP2 may be referred to as an “auxiliary display panel” or “external display panel”.

The first display panel DP1 may include a first display part DA1-F. The second display panel DP2 may include a second display part DA2-F. The area of the second display panel DP2 may be smaller than the area of the first display panel DP1. The area of the first display part DA1-F, which corresponds to the size of the first display panel DP1, may be larger than the area of the second display part DA2-F, which corresponds to the size of the second display panel DP2.

While the electronic device 1000 is unfolded, the first display part DA1-F may have a plane that is parallel to or substantially parallel to a first direction DR1 and a second direction DR2. A thickness direction of the electronic device 1000 may be parallel to or substantially parallel to a third direction DR3 crossing or intersecting the first direction DR1 and the second direction DR2. Accordingly, front surfaces (e.g., top/upper surfaces) and rear surfaces (e.g., bottom/lower surfaces) of members constituting the electronic device 1000 may be defined with respect to the third direction DR3.

The first display panel DP1 or the first display part DA1-F may include a folding area FA that may be folded and unfolded, and a plurality of non-folding areas NFA1 and NFA2 spaced apart from each other with the folding area FA interposed therebetween. The second display panel DP2 may overlap with one of the plurality of non-folding areas NFA1 and NFA2. For example, the second display panel DP2 may overlap with the first non-folding area NFA1.

A display direction of a first image IM1a that is displayed in a portion of the first display panel DP1, for example, such as in the first non-folding area NFA1, may face away from (e.g., may be opposite to) a display direction of a second image IM2a that is displayed in the second display panel DP2. For example, the first image IM1a may be displayed in the third direction DR3, and the second image IM2a may be displayed in a fourth direction DR4, which is an opposite direction to the third direction DR3.

In an embodiment of the present disclosure, the folding area FA may be bent around a folding axis extending in a direction parallel to or substantially parallel to a long side (e.g., a long edge) of the electronic device 1000, for example, such as in a direction parallel to or substantially parallel to the second direction DR2. The folding area FA may have a suitable curvature (e.g., a given or predetermined curvature) and a suitable radius of curvature (e.g., a given or predetermined radius of curvature) when the electronic device 1000 is folded. The first non-folding area NFA1 and the second non-folding area NFA2 may face each other, and in this case, the electronic device 1000 may be inner-folded so that the first display part DA1-F is not exposed to the outside.

In an embodiment of the present disclosure, the electronic device 1000 may be outer-folded so that the first display part DA1-F is exposed to the outside. In an embodiment of the present disclosure, the electronic device 1000 may be capable of both in-folding and out-folding from an unfolded state, but the present disclosure is not limited thereto.

FIG. 1A illustrates that one folding area FA is defined (e.g., is provided or included) in the electronic device 1000, but the present disclosure is not limited thereto. For example, a plurality of folding axes and a plurality of folding areas corresponding thereto may be defined in the electronic device 1000. The electronic device 1000 may be in-folded or out-folded in a state in which each of the plurality of folding areas is unfolded.

According to an embodiment of the present disclosure, at least one of the first display panel DP1 or the second display panel DP2 may sense an input by the pen PN, even though a digitizer is not included therein. Accordingly, because the digitizer for sensing the pen PN may be omitted, an increase in the thickness of the electronic device 1000, an increase in the weight of the electronic device 1000, and a decrease in a flexibility of the electronic device 1000, due to the addition of a digitizer, may not occur. Accordingly, the second display panel DP2, as well as the first display panel DP1, may be designed to sense the pen PN.

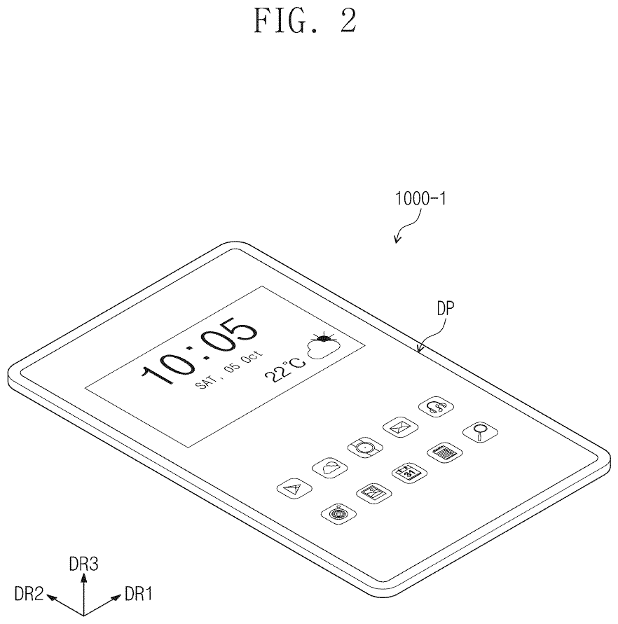

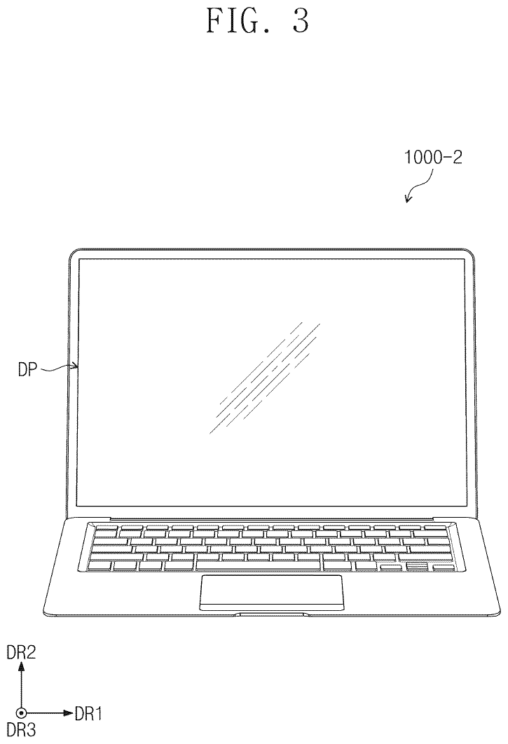

FIG. 2 is a perspective view of an electronic device 1000-1 according to an embodiment of the present disclosure. FIG. 3 is a perspective view of an electronic device 1000-2 according to an embodiment of the present disclosure.

FIG. 2 shows that the electronic device 1000-1 is a bar-kind of electronic device, such as a mobile phone or tablet, and the electronic device 1000-1 may include a display panel DP. FIG. 3 illustrates an example in which the electronic device 1000-2 is a notebook, and the electronic device 1000-2 may include the display panel DP.

In an embodiment of the present disclosure, the display panel DP may sense external inputs applied from the outside. The external input may be an input of the user. The input of the user may include various suitable kinds of external inputs, such as a part of a user's body, the pen PN (e.g., refer to FIG. 1A), light, heat, and/or pressure.

According to an embodiment of the present disclosure, even though the display panel DP may not include the digitizer, the display panel DP may sense an input by the pen PN. Accordingly, because the digitizer for sensing the pen PN may omitted, an increase in the thickness of the electronic device 1000-1 or 1000-2, and an increase in the weight of the electronic device 1000-1 or 1000-2, due to the addition of a digitizer, may not occur.

An example in which the electronic device 1000 is of a foldable kind is illustrated in FIG. 1A, and an example in which the electronic device 1000-1 is of a bar kind is illustrated in FIG. 2. However, the present disclosure is not limited thereto. For example, the electronic device according to various embodiments of the present disclosure may be applicable to various suitable kinds of electronic devices, such as a rollable electronic device, a slidable electronic device, and a stretchable electronic device.

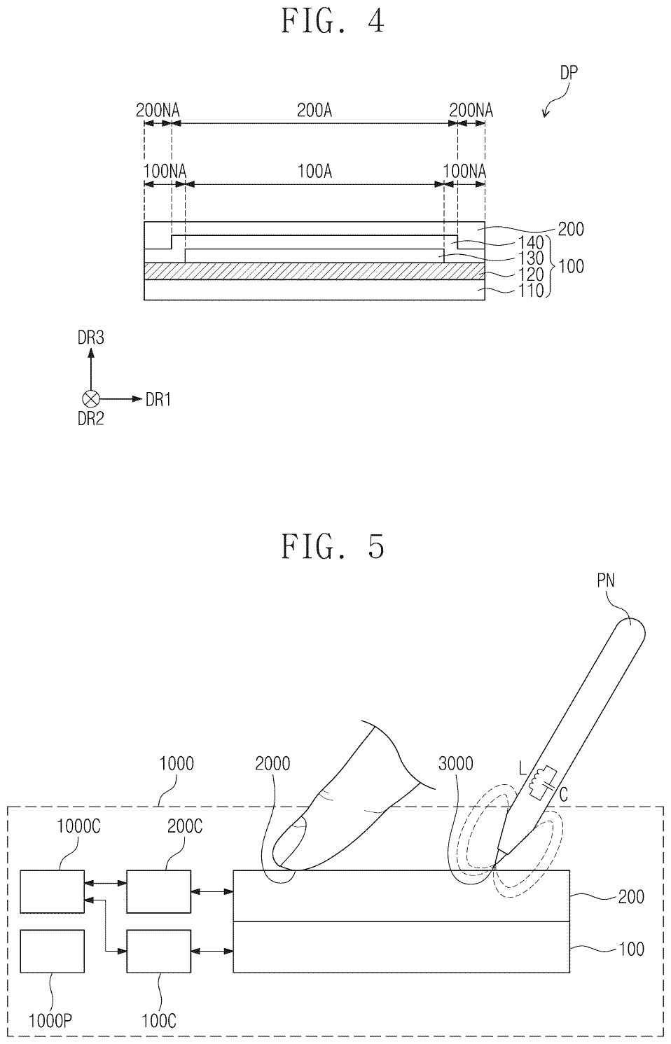

FIG. 4 is a schematic cross-sectional view of the display panel DP according to an embodiment of the present disclosure.

Referring to FIG. 4, the display panel DP may include a display layer 100 and a sensor layer 200.

The display layer 100 may be a component that substantially generates an image. A display area 100A and a non-display area 100NA adjacent to the display area 100A may be defined in the display layer 100. An image may be displayed in the display area 100A.

The display layer 100 may be a light emitting display layer. For example, the display layer 100 may be an organic light emitting display layer, an inorganic light emitting display layer, an organic-inorganic light emitting display layer, a quantum dot display layer, a micro-LED display layer, or a nano-LED display layer. The display layer 100 may include a base layer 110, a circuit layer 120, a light emitting element layer 130, and an encapsulation layer 140.

The base layer 110 may be a member that provides a base surface on which the circuit layer 120 is disposed. The base layer 110 may include a multi-layered structure or a single-layer structure. The base layer 110 may be a glass substrate, a metal substrate, a silicon substrate, or a polymer substrate, but the present disclosure is not particularly limited thereto.

The circuit layer 120 may be disposed on the base layer 110. The circuit layer 120 may include an insulating layer, a semiconductor pattern, a conductive pattern, a signal line, and the like. The insulating layer, the semiconductor layer, and the conductive layer may be formed on the base layer 110 in a suitable manner, such as coating, evaporation, or the like. The insulating layer, the semiconductor layer, and the conductive layer may be selectively patterned by performing a photolithography process multiple times.

The light emitting element layer 130 may be disposed on the circuit layer 120. The light emitting element layer 130 may include a light emitting device. For example, the light emitting element layer 130 may include an organic light emitting material, an inorganic light emitting material, an organic-inorganic light emitting material, a quantum dot, a quantum rod, a micro-LED, or a nano-LED.

The encapsulation layer 140 may be disposed on the light emitting element layer 130. The encapsulation layer 140 may protect the light emitting element layer 130 from foreign substances, such as moisture, oxygen, and dust particles.

The sensor layer 200 may be disposed on the display layer 100. A sensing area 200A and a peripheral area 200NA adjacent to the sensing area 200A may be defined in the sensor layer 200. The sensing area 200A may overlap with the display area 100A. The peripheral area 200NA may overlap with the non-display area 100NA.

According to an embodiment of the present disclosure, the area of the sensing area 200A may be larger than the area of the display area 100A. Accordingly, a portion of the sensing area 200A may overlap with the non-display area 100NA. In this case, even when an input occurs at an area adjacent to the boundary between the display area 100A and the non-display area 100NA, a signal may be sufficiently recognized, because the sensing area 200A may overlap with a portion of the non-display area 100NA. Therefore, an accuracy of coordinates of a touch input onto the outskirt of the display area 100A may be improved. The area of the sensing area 200A that is larger than the area of the display area 100A will be described in more detail below.

The sensor layer 200 may sense an external input applied from the outside. The sensor layer 200 may be a sensor that is integrally formed continuously during the process of manufacturing the display layer 100, or the sensor layer 200 may be an external sensor that is attached to the display layer 100. The sensor layer 200 may be referred to as a “sensor”, an “input sensing layer”, an “input sensing panel”, or an “electronic device for sensing input coordinates”.

According to an embodiment of the present disclosure, the sensor layer 200 may sense both inputs from a passive-kind of input means, such as the user's body, and an input device for generating a magnetic field of a suitable resonance frequency (e.g., a predetermined resonant frequency). The input device may be referred to as a “pen”, an “input pen”, a “magnetic pen”, a “stylus pen”, or an “electromagnetic resonance pen”.

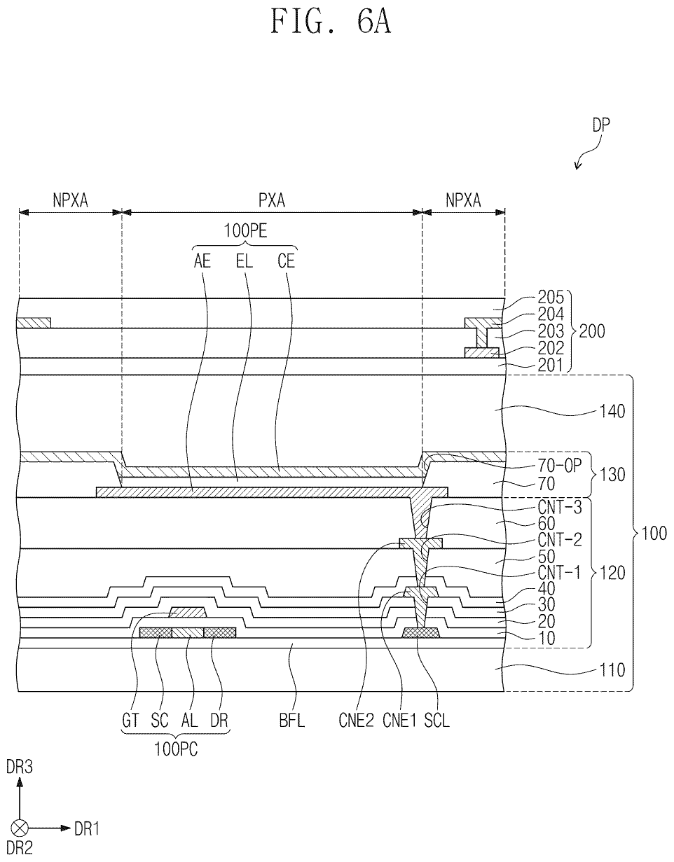

FIG. 5 is a diagram illustrating an operation of the electronic device 1000 according to an embodiment of the present disclosure.

Referring to FIG. 5, the electronic device 1000 may include the display layer 100, the sensor layer 200, a display driver 100C, a sensor driver 200C, a main driver 1000C, and a power supply circuit 1000P.

The sensor layer 200 may sense a first input 2000 or a second input 3000 applied from the outside. Each of the first input 2000 and the second input 3000 may be an input means capable of providing a change in a capacitance of the sensor layer 200, or an input means capable of causing an induced current in the sensor layer 200. For example, the first input 2000 may be a passive kind of an input method, such as a user's body. The second input 3000 may be an input by the pen PN, or an input by a Radio Frequency Integrated Circuit (RFIC) tag. For example, the pen PN may be a passive-kind of pen or an active-kind of pen.

In an embodiment of the present disclosure, the pen PN may be a device that generates a magnetic field of a suitable resonant frequency (e.g., a given or predetermined resonant frequency). The pen PN may transmit an output signal based on an electromagnetic resonance manner. The pen PN may be referred to as an “input device”, an “input pen”, a “magnetic pen”, a “stylus pen”, or an “electromagnetic resonance pen”.

The pen PN may include an RLC resonant circuit. The RLC resonant circuit may include an inductor “L” and a capacitor “C”. In an embodiment of the present disclosure, the RLC resonant circuit may be a variable resonant circuit having a resonant frequency that is variable. In this case, the inductor “L” may be a variable inductor, and/or the capacitor “C” may be a variable capacitor. However, the present disclosure is not limited thereto.

The inductor “L” generates a current by a magnetic field formed in the electronic device 1000, for example, such as in the sensor layer 200. However, the present disclosure is not particularly limited thereto. For example, when the pen PN operates as an active kind, the pen PN may generate a current even though a magnetic field is not provided from the outside. The generated current may be transferred to the capacitor “C”. The capacitor “C” charges the current input from the inductor “L”, and discharges the charged current to the inductor “L”. Afterwards, the inductor “L” may emit a magnetic field at the resonant frequency. The induced current may flow in the sensor layer 200 by the magnetic field formed by the pen PN, and the induced current may be transferred to the sensor driver 200C as a receive signal (e.g., a sensing signal or a signal).

The main driver 1000C may control all of the operations of the electronic device 1000. For example, the main driver 1000C may control operations of the display driver 100C and the sensor driver 200C. The main driver 1000C may include at least one microprocessor, and may further include a graphics processor. The main driver 1000C may be referred to as an “application processor”, a “central processing unit”, or a “main processor”.

The display driver 100C may drive the display layer 100. The display driver 100C may receive image data and a control signal from the main driver 1000C. The control signal may include various suitable signals. For example, the control signal may include an input vertical synchronization signal, an input horizontal synchronization signal, a main clock signal, and a data enable signal.

The sensor driver 200C may drive the sensor layer 200. The sensor driver 200C may receive a control signal from the main driver 1000C. The control signal may include a clock signal of the sensor driver 200C. Also, the control signal may further include a mode selection signal for selecting driving modes of the sensor driver 200C and the sensor layer 200.

The sensor driver 200C may be implemented with an integrated circuit (IC), and may be electrically connected to the sensor layer 200. For example, the sensor driver 200C may be mounted directly on a suitable area (e.g., a predetermined area) of the display panel, or may be mounted on a separate printed circuit board in a chip-on-film (COF) method to be electrically connected to the sensor layer 200.

The sensor driver 200C and the sensor layer 200 may selectively operate in a first mode or a second mode. For example, the first mode may be a mode in which a touch input, for example, such as the first input 2000, is sensed. The second mode may be a mode for sensing an input by the pen PN, for example, such as the second input 3000. The first mode may be referred to as a “touch sensing mode”, and the second mode may be referred to as a “pen sensing mode”.

Switching between the first mode and the second mode may be accomplished in a variety of suitable manners. For example, the sensor driver 200C and the sensor layer 200 may be driven in a time-division method in the first mode and the second mode, and may sense the first input 2000 and the second input 3000. As another example, the switching between the first mode and the second mode may occur due to a user's selection or the user's specific action (e.g., an input), either the first mode or the second mode may be activated or deactivated by activating or deactivating a specific application, or one mode may be switched to the other mode. As another example, while operating alternately in the first mode and the second mode, the sensor driver 200C and the sensor layer 200 may be maintained in the first mode when the first input 2000 is sensed, or may be maintained in the second mode when the second input 3000 is sensed.

The sensor driver 200C may calculate coordinate information of an input based on a signal received from the sensor layer 200, and may provide the main driver 1000C with a coordinate signal having the coordinate information. The main driver 1000C executes an operation corresponding to a user input based on the coordinate signal. For example, the main driver 1000C may operate the display driver 100C, such that a new application image is displayed on the display layer 100.

The power supply circuit 1000P may include a power management integrated circuit (PMIC). The power supply circuit 1000P may generate a plurality of driving voltages for driving the display layer 100, the sensor layer 200, the display driver 100C, and the sensor driver 200C. For example, the plurality of driving voltages may include a high gate voltage, a low gate voltage, a first driving voltage (e.g., an ELVSS voltage), a second driving voltage (e.g., an ELVDD voltage), an initialization voltage, and the like, but the present disclosure is not limited thereto.

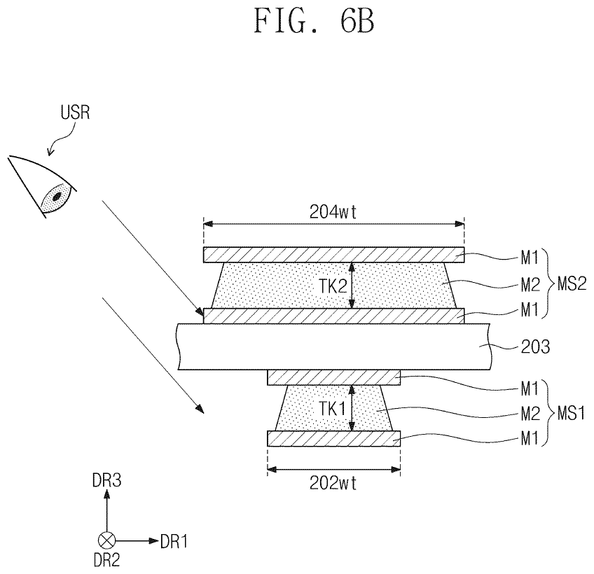

FIG. 6A is a cross-sectional view of the display panel DP according to an embodiment of the present disclosure.

Referring to FIG. 6A, at least one buffer layer BFL may be formed on an upper surface of the base layer 110. The buffer layer BFL may improve a bonding force between the base layer 110 and a semiconductor pattern. The buffer layer BFL may be formed in a multi-layered structure. As another example, the display layer 100 may further include a barrier layer. The buffer layer BFL may include at least one of silicon oxide, silicon nitride, or silicon oxynitride. For example, the buffer layer BFL may include a structure in which a silicon oxide layer and a silicon nitride layer are stacked alternately.

A semiconductor pattern SC, AL, DR, and SCL may be disposed on the buffer layer BFL. The semiconductor pattern SC, AL, DR, and SCL may include polysilicon. However, the present disclosure is not limited thereto. For example, the semiconductor pattern SC, AL, DR, and SCL may include amorphous silicon, a low-temperature polycrystalline silicon, or an oxide semiconductor.

FIG. 6A illustrates a part of the semiconductor patterns SC, AL, DR, and SCL, and the semiconductor pattern may be further disposed in another area in another view. The semiconductor patterns SC, AL, DR, and SCL may be arranged across pixels in compliance with a suitable rule (e.g., a specific or predetermined rule). Electrical properties of the semiconductor pattern SC, AL, DR, and SCL may be differently determined depending on whether or not it is doped. The semiconductor pattern SC, AL, DR, and SCL may include a first area SC, DR, or SCL having a conductivity that is relatively high, and a second area AL having a conductivity that is relatively low. The first area SC, DR, or SCL may be doped with an N-type dopant or a P-type dopant. A P-type transistor may include an area doped with the P-type dopant, and an N-type transistor may include an area doped with the N-type dopant. The second area AL may be an undoped area, or an area doped with a concentration lower than a concentration in the first area SC, DR, or SCL.

The conductivity of the first area SC, DR, or SCL may be greater than the conductivity of the second area AL, and may substantially serve as an electrode or a signal line. The second area AL may substantially correspond to an active area (e.g., a channel) AL of a transistor 100PC. In other words, a portion AL of the semiconductor pattern SC, AL, DR, and SCL may be the active area AL of the transistor 100PC, another portion SC and DR thereof may be the source area SC or the drain area DR of the transistor 100PC, and another portion SCL thereof may be an connection electrode or the connection signal line SCL.

Each of the pixels may be expressed by an equivalent circuit including a plurality of transistors, at least one capacitor, and at least one light emitting element. The equivalent circuit of a pixel may be modified in various suitable forms. FIG. 6A shows one transistor 100PC and one light emitting element 100PE included in a pixel.

The source area SC, the active area AL, and the drain area DR of the transistor 100PC may be formed from the semiconductor pattern SC, AL, DR, and SCL. The source area SC and the drain area DR may extend in directions facing away from (e.g., opposite to) each other from the active area AL in a cross-sectional view. A portion of the connection signal line SCL formed from the semiconductor patterns SC, AL, DR, and SCL is illustrated in FIG. 6A. In another view, the connection signal line SCL may be connected to the drain area DR of the transistor 100PC (e.g., in a plan view).

A first insulating layer 10 may be disposed on the buffer layer BFL. The first insulating layer 10 may overlap with a plurality of pixels in common, and may cover the semiconductor pattern SC, AL, DR, and SCL. The first insulating layer 10 may be an inorganic layer and/or an organic layer, and may have a single-layer or multi-layered structure. The first insulating layer 10 may include at least one of aluminum oxide, titanium oxide, silicon oxide, silicon nitride, silicon oxynitride, zirconium oxide, or hafnium oxide. In an embodiment, the first insulating layer 10 may be a single silicon oxide layer. As well as the first insulating layer 10, an insulating layer of the circuit layer 120 described in more detail below may be an inorganic layer and/or an organic layer, and may have a single-layer or multi-layered structure. The inorganic layer may include at least one of the above inorganic materials, but the present disclosure is not limited thereto.

A gate GT of the transistor 100PC is disposed on the first insulating layer 10. The gate GT may be a part of a metal pattern. The gate GT overlaps with the active area AL. The gate GT may function as a mask in a process of doping or reducing the semiconductor pattern SC, AL, DR, and SCL.

A second insulating layer 20 may be disposed on the first insulating layer 10, and may cover the gate GT. The second insulating layer 20 may overlap with the pixels in common. The second insulating layer 20 may be an inorganic layer and/or an organic layer, and may have a single-layer or multi-layered structure. The second insulating layer 20 may include at least one of silicon oxide, silicon nitride, or silicon oxynitride. In an embodiment, the second insulating layer 20 may have a multi-layered structure including a silicon oxide layer and a silicon nitride layer.

A third insulating layer 30 may be disposed on the second insulating layer 20. The third insulating layer 30 may have a single-layer or multi-layered structure. In an embodiment, the third insulating layer 30 may have a multi-layered structure including a silicon oxide layer and a silicon nitride layer.

A first connection electrode CNE1 may be disposed on the third insulating layer 30. The first connection electrode CNE1 may be connected to the connection signal line SCL through a contact hole CNT-1 penetrating the first, second, and third insulating layers 10, 20, and 30.

A fourth insulating layer 40 may be disposed on the third insulating layer 30. The fourth insulating layer 40 may be a single silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected with the first connection electrode CNE1 through a contact hole CNT-2 penetrating the fourth insulating layer 40 and the fifth insulating layer 50.

A sixth insulating layer 60 may be disposed on the fifth insulating layer 50, and may cover the second connection electrode CNE2. The sixth insulating layer 60 may be an organic layer.

The light emitting element layer 130 may be disposed on the circuit layer 120. The light emitting element layer 130 may include the light emitting element 100PE. For example, the light emitting element layer 130 may include an organic light emitting material, an inorganic light emitting material, an organic-inorganic light emitting material, a quantum dot, a quantum rod, a micro-LED, or a nano-LED. Hereinafter, for convenience of illustration, an example in which the light emitting element 100PE is an organic light emitting element will be described in more detail, but the present disclosure is not limited thereto.

The light emitting element 100PE may include a first electrode AE, a light emitting layer EL, and a second electrode CE.

The first electrode AE may be disposed on the sixth insulating layer 60. The first electrode AE may be connected with the second connection electrode CNE2 through a contact hole CNT-3 penetrating the sixth insulating layer 60.

A pixel defining film 70 may be disposed on the sixth insulating layer 60, and may cover a portion of the first electrode AE. An opening 70-OP is defined in the pixel defining film 70. The opening 70-OP of the pixel defining film 70 exposes at least a portion of the first electrode AE.

The first display part DA1-F (e.g., refer of FIG. 1A) may include an emission area PXA, and a non-emission area NPXA adjacent to the emission area PXA. The non-emission area NPXA may surround (e.g., around a periphery of) the emission area PXA. In an embodiment, the emission area PXA is defined to correspond to a partial area of the first electrode AE exposed by the opening 70-OP.

The light emitting layer EL may be disposed on the first electrode AE. The light emitting layer EL may be disposed in an area defined by the opening 70-OP. FIG. 6A shows an example of the light emitting layer EL disposed within the opening 70-OP, but the present disclosure is not particularly limited thereto. For example, the light emitting layer EL may extend to cover a portion of a side surface of the pixel defining film 70 defining the opening 70-OP, and a top surface of the pixel defining film 70.

In an embodiment of the present disclosure, the light emitting layer EL may be separately formed for each of the pixels. When the light emitting layer EL is independently formed for each pixel, each of the light emitting layers EL may emit light of at least one of a blue color, a red color, or a green color. However, the present disclosure is not limited thereto. For example, the light emitting layer EL may be connected to and included in each of the pixels in common. In this case, the light emitting layer EL may provide a blue light, or may provide a white light.

The second electrode CE may be disposed on the light emitting layer EL. The second electrode CE may have an integrated shape, and may be included in a plurality of the pixels in common.

In an embodiment of the present disclosure, a hole control layer may be interposed between the first electrode AE and the light emitting layer EL. The hole control layer may be disposed in common in the emission area PXA and the non-emission area NPXA. The hole control layer may include a hole transport layer, and may further include a hole injection layer. An electron control layer may be disposed between the light emitting layer EL and the second electrode CE. The electron control layer may include an electron transport layer, and may further include an electron injection layer. The hole control layer and the electron control layer may be formed in common in a plurality of the pixels by using an open mask or an inkjet process.

The encapsulation layer 140 may be disposed on the light emitting element layer 130. The encapsulation layer 140 may include an inorganic layer, an organic layer, and an inorganic layer, which are sequentially stacked, but the layers constituting the encapsulation layer 140 are not limited thereto. The inorganic layers may protect the light emitting element layer 130 from moisture and oxygen, and the organic layer may protect the light emitting element layer 130 from a foreign material such as dust particles. The inorganic layers may include a silicon nitride layer, a silicon oxynitride layer, a silicon oxide layer, a titanium oxide layer, or an aluminum oxide layer. The organic layer may include an acrylic-based organic layer, but the present disclosure is not limited thereto.

The sensor layer 200 may include a base layer 201, a first conductive layer 202, a first insulating layer 203, a second conductive layer 204, and a second insulating layer 205.

The base layer 201 may be an inorganic layer including at least one of silicon nitride, silicon oxynitride, or silicon oxide. As another example, the base layer 201 may be an organic layer including an epoxy resin, an acrylate resin, or an imide-based resin. The base layer 201 may have a single-layer structure, or may have a multi-layered structure stacked in the third direction DR3. In an embodiment of the present disclosure, the sensor layer 200 may not include the base layer 201.

Each of the first conductive layer 202 and the second conductive layer 204 may have a single-layer structure, or may have a structure in which multiple layers are stacked in the third direction DR3.

Each of the first conductive layer 202 and the second conductive layer 204 of the single-layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer, such as poly(3,4-ethylenedioxythiophene) (PEDOT), a metal nanowire, graphene, and/or the like.

Each of the first conductive layer 202 and the second conductive layer 204 of the multi-layered structure may include a plurality of metal layers. The metal layers may have, for example, a three-layered structure of titanium/aluminum/titanium. The conductive layer of the multi-layered structure may include at least one metal layer and at least one transparent conductive layer.

In an embodiment of the present disclosure, the thickness of the first conductive layer 202 may be greater than or equal to the thickness of the second conductive layer 204. When the thickness of the first conductive layer 202 is greater than the thickness of the second conductive layer 204, a resistance of a component (e.g., an electrode, a pattern, or a bridge pattern) included in the first conductive layer 202 may be reduced. Moreover, because the first conductive layer 202 may be disposed under the second conductive layer 204, a probability that the components included in the first conductive layer 202 are recognized by an external light reflection may be lower than that of the second conductive layer 204, even though the thickness of the first conductive layer 202 may be increased.

At least one of the first insulating layer 203 or the second insulating layer 205 may include an inorganic film. The inorganic film may include at least one of aluminum oxide, titanium oxide, silicon oxide, silicon nitride, silicon oxynitride, zirconium oxide, or hafnium oxide.

At least one of the first insulating layer 203 or the second insulating layer 205 may include an organic film. The organic film may include at least one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

Hereinafter, for convenience of illustration, the sensor layer 200 may be described in more detail as including a total of two conductive layers (e.g., the first conductive layer 202 and the second conductive layer 204), but the present disclosure is not particularly limited thereto. For example, the sensor layer 200 may include three or more conductive layers.

FIG. 6B is a cross-sectional view illustrating a partial configuration of the sensor layer 200 according to an embodiment of the present disclosure.

Referring to FIGS. 6A and 6B, a second width 204wt of a second mesh line MS2 included in the second conductive layer 204 may be greater than or equal to a first width 202wt of a first mesh line MS1 included in the first conductive layer 202. When a user USR watches the first mesh line MS1 and the second mesh line MS2 from a side, the first mesh line MS1 has a smaller width than that of the second mesh line MS2, and thus, a probability that the first mesh line MS1 may be recognized by the user USR may be reduced.

Each of the first mesh line MS1 and the second mesh line MS2 may include first metal layers M1, and a second metal layer M2 interposed between the first metal layers M1. The first metal layers M1 may include titanium (Ti), and the second metal layer M2 may include aluminum (AI). However, the present disclosure is not particularly limited thereto.

In an embodiment of the present disclosure, a first thickness TK1 of the second metal layer M2 of the first mesh line MS1 and a second thickness TK2 of the second metal layer M2 of the second mesh line MS2 may be the same or substantially the same as each other, but the present disclosure is not particularly limited thereto. For example, the first thickness TK1 may be thicker than the second thickness TK2. As another example, the second thickness TK2 may be thicker than the first thickness TK1. In an embodiment of the present disclosure, each of the first thickness TK1 and the second thickness TK2 may be 1000 Ångström or more, for example, such as 6000 Ångström.

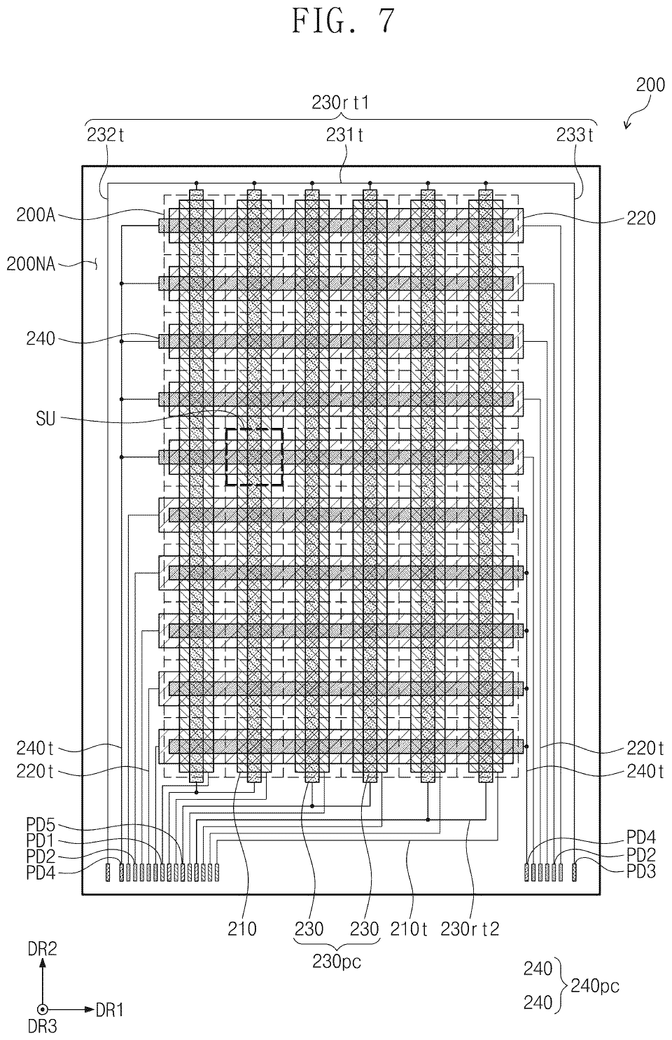

FIG. 7 is a plan view of the sensor layer 200 according to an embodiment of the present disclosure.

Referring to FIG. 7, the sensing area 200A and the peripheral area 200NA adjacent to the sensing area 200A may be defined in the sensor layer 200.

The sensor layer 200 may include a plurality of first electrodes 210, a plurality of second electrodes 220, a plurality of third electrodes 230, and a plurality of fourth electrodes 240, which are disposed in the sensing area 200A.

The first electrodes 210 may cross or intersect the second electrodes 220. Each of the first electrodes 210 may extend in the second direction DR2. The first electrodes 210 may be arranged to be spaced from each other in the first direction DR1. Each of the second electrodes 220 may extend in the first direction DR1. The second electrodes 220 may be arranged to be spaced from each other in the second direction DR2. A sensing unit (e.g., a sensing region) SU of the sensor layer 200 may refer to an area in which one first electrode 210 and one second electrode 220 cross each other.

In FIG. 7, 6 first electrodes 210 and 10 second electrodes 220 are illustrated as an example, and 60 sensing units SU are illustrated as an example. However, the number of first electrodes 210 and the number of second electrodes 220 are not limited thereto.

Each of the third electrodes 230 may extend in the second direction DR2. The third electrodes 230 may be arranged to be spaced from each other in the first direction DR1. One third electrode 230 may at least partially overlap with one first electrode 210. According to an embodiment of the present disclosure, a capacitance (e.g., a coupling capacitance) between one first electrode 210 and one third electrode 230 may be adjusted by adjusting the overlapping area of the one first electrode 210 and the one third electrode 230.

In an embodiment of the present disclosure, at least some of the third electrodes 230 may be connected in parallel with each other. For example, FIG. 7 shows that two third electrodes 230 are connected in parallel with each other to form a first electrode group 230pc. Three first electrode groups 230pc may be arranged along the first direction DR1. However, the number of third electrodes 230 constituting the first electrode group 230pc is not limited thereto. For example, one first electrode group 230pc may include only one third electrode 230, or may include three or more third electrodes 230.

As the number of third electrodes 230 included in the first electrode group 230pc and connected in parallel with each other increases, the resistance of the first electrode group 230pc may be lowered, thereby improving a power efficiency and a sensing sensitivity. On the other hand, as the number of third electrodes 230 included in the first electrode group 230pc decreases, a loop coil pattern formed by using the first electrode group 230pc may be implemented in more diverse forms.

The fourth electrodes 240 may be arranged along the second direction DR2, and the fourth electrodes 240 may extend in the first direction DR1. One fourth electrode 240 may at least partially overlap with one second electrode 220. According to an embodiment of the present disclosure, a capacitance (e.g., a coupling capacitance) between one second electrode 220 and one fourth electrode 240 may be adjusted by adjusting the overlapping area of the one second electrode 220 and the one fourth electrode 240.

In an embodiment of the present disclosure, at least some of the fourth electrodes 240 may be electrically connected to each other to form one second electrode group 240pc. For example, FIG. 7 shows that five fourth electrodes 240 are connected to the same trace line (e.g., a group trace line 240t) to form one second electrode group 240pc. Accordingly, FIG. 7 shows that two second electrode groups 240pc are arranged along the second direction DR2. However, the number of fourth electrodes 240 constituting one second electrode group 240pc is not limited thereto. For example, the number of fourth electrodes 240 constituting one second electrode group 240pc may be 10. In this case, the sensor layer 200 may include only one second electrode group 240pc.

The sensor layer 200 may further include a plurality of first trace lines 210t, a plurality of first pads PD1 connected to the first trace lines 210t in a one-to-one correspondence, a plurality of second trace lines 220t, and a plurality of second pads PD2 connected to the second trace lines 220t in a one-to-one correspondence, which may be disposed in the peripheral area 200NA. The first trace lines 210t may be electrically connected to the first electrodes 210 in a one-to-one correspondence. The second trace lines 220t may be electrically connected to the second electrodes 220 in a one-to-one correspondence.

The sensor layer 200 may further include a first loop trace line 230rt1 in the peripheral area 200NA, a plurality of third pads PD3 connected to one end and another end (e.g., an opposite end) of the first loop trace line 230rt1, group trace lines 240t, fourth pads PD4 connected to the group trace lines 240t in a one-to-one correspondence, second loop trace lines 230rt2, and fifth pads PD5 connected to the second loop trace lines 230rt2 in a one-to-one correspondence.

The first loop trace line 230rt1 may be electrically connected to the third electrodes 230. In an embodiment of the present disclosure, the first loop trace line 230rt1 may be electrically connected to all of the third electrodes 230. The first loop trace line 230rt1 may include a first line portion 231t extending in the first direction DR1 and electrically connected to the third electrodes 230, a second line portion 232t extending from a first end of the first line portion 231t in the second direction DR2, and a third line portion 233t extending from a second end of the first line portion 231t in the second direction DR2.

In an embodiment of the present disclosure, each of a resistance of the second line portion 232t and a resistance of the third line portion 233t may be the same or substantially the same as a resistance of one electrode group among the first electrode groups 230pc. Accordingly, each of the second line portion 232t and the third line portion 233t may serve as the first electrode group 230pc, and the same effect in which the third electrodes 230 are also placed in the peripheral area 200NA may be obtained. For example, one of the second line portion 232t or the third line portion 233t and one of the third electrodes 230 may form a coil. Accordingly, a pen located in an area close to the peripheral area 200NA may also be sufficiently charged by the loop including the second line portion 232t or the third line portion 233t.

In an embodiment of the present disclosure, to adjust the resistance of the second line portion 232t and the resistance of the third line portion 233t, the width of the second line portion 232t in the first direction DR1 and the width of the third line portion 233t in the first direction DR1 may be adjusted. However, the present disclosure is not limited thereto. For example, the first to third line portions 231t, 232t, and 233t may have the same or substantially the same width as each other.

The second loop trace lines 230rt2 may be connected to the first electrode groups 230pc in a one-to-one correspondence. In other words, the number of second loop trace lines 230rt2 may correspond to the number of first electrode groups 230pc. FIG. 7 shows three second loop trace lines 230rt2 and three first electrode groups 230pc.

In an embodiment of the present disclosure, the second loop trace lines 230rt2 and the fifth pads PD5 may be omitted as needed or desired, and a charging driving mode for charging the pen may be omitted. In this case, the sensor layer 200 may sense an input from an active-kind of pen capable of emitting a magnetic field, even when a magnetic field is not provided from the sensor layer 200.

The group trace lines 240t may be spaced from each other with the sensing area 200A interposed therebetween. The group trace lines 240t may be electrically connected to the second electrode groups 240pc in a one-to-one correspondence. FIG. 7 shows that two second electrode groups 240pc are arranged as an example. The group trace line 240t connected to one second electrode group 240pc and the group trace line 240t connected to another second electrode group 240pc may be spaced from each other with the sensing area 200A interposed therebetween. However, the present disclosure is not particularly limited thereto. The group trace lines 240t may also be referred to as trace lines.

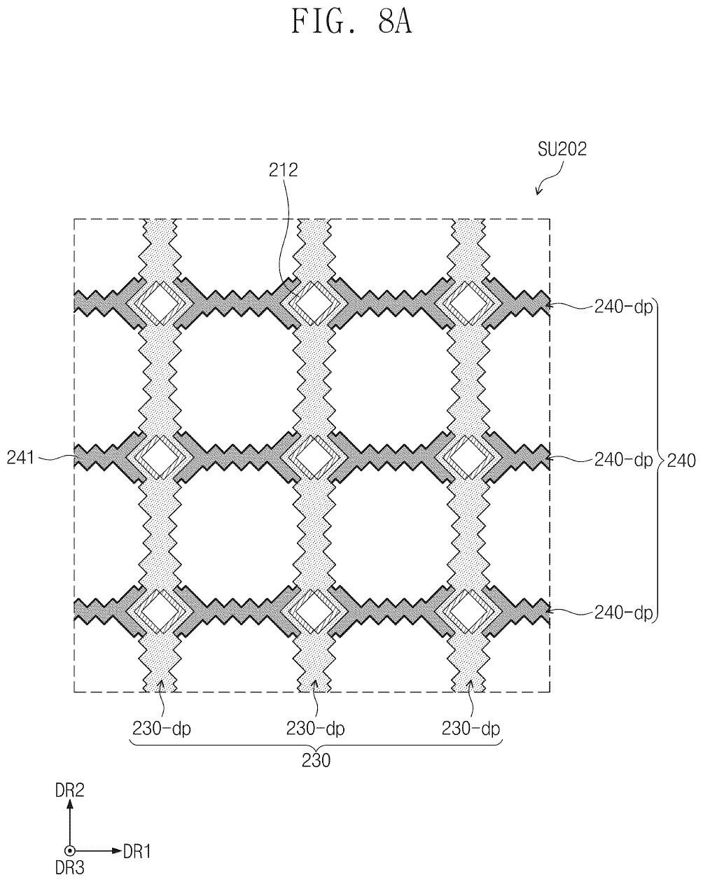

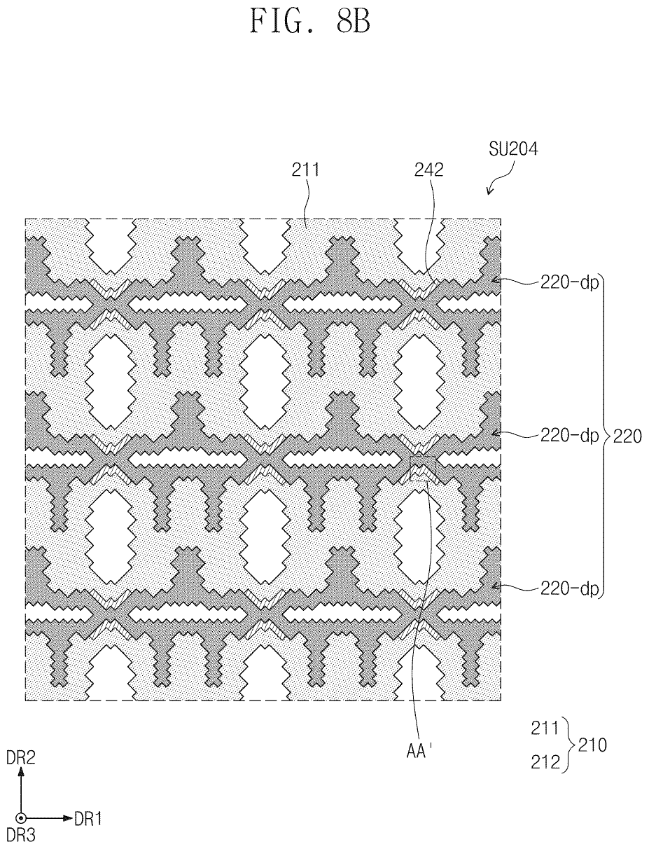

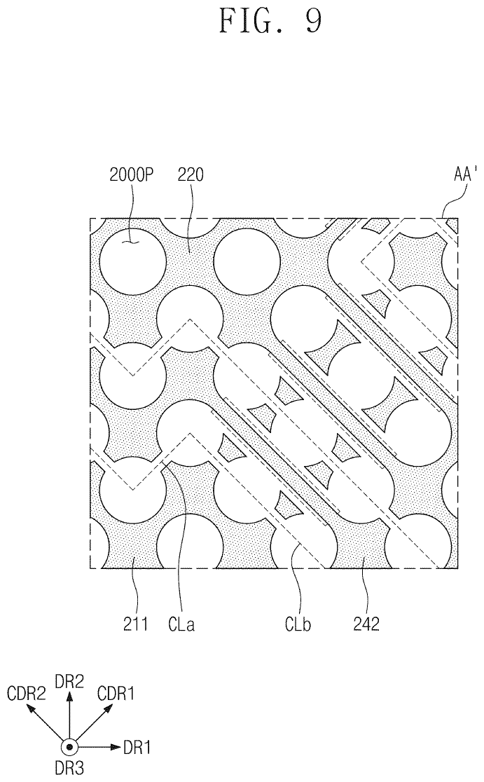

FIG. 8A is a plan view showing a first conductive layer SU202 of the sensing unit SU according to an embodiment of the present disclosure. FIG. 8B is a plan view showing a second conductive layer SU204 of the sensing unit SU according to an embodiment of the present disclosure. FIG. 9 is an enlarged plan view of the region AA′ shown in FIG. 8B.

For convenience of illustration, FIGS. 8A and 8B show boundaries of the components with lines rather than showing the geometry of a mesh structure. In other words, the lines shown in FIGS. 8A and 8B may be understood to correspond to lines from which the mesh structure of FIGS. 8A and 8B are removed, and in FIG. 9, lines CLa, CLb are shown as dashed lines.

The shape of the sensing unit SU shown in FIGS. 8A, 8B, and 9 is an example, and the present disclosure is not limited thereto. The shape of the sensing unit SU may be variously modified as needed or desired.

Referring to FIGS. 8A and 8B, the first electrode 210 may include a plurality of first patterns 211, and a plurality of first bridge patterns 212 electrically connected to the first patterns 211. The first patterns 211 that are spaced apart from one another in the second direction DR2 may be electrically connected to each other by the first bridge patterns 212. The first patterns 211 may be included in the second conductive layer SU204, and the first bridge patterns 212 may be included in the first conductive layer SU202.

Two first patterns 211 on one first electrode 210, which are adjacent to each other in the second direction DR2, may be electrically connected to each other by six first bridge patterns 212. An increase in the number of first bridge patterns 212 arranged along the first direction DR1, which crosses an extension direction of the first electrode 210 (for example, the second direction DR2), may correspond to an increase in the number of signal passes parallel to the extension direction of the first electrode 210. Thus, as the number of signal passes increases, a resistance of the first electrode 210 may decrease. As a result, the sensing sensitivity of the sensor layer 200 may be improved.

The second electrode 220 may include a plurality of first split electrodes 220-dp spaced apart from each other in the second direction DR2. Each of the first split electrodes 220-dp may extend in the first direction DR1, and the first split electrodes 220-dp may be spaced apart from each other in the second direction DR2. The first split electrodes 220-dp may be included in the second conductive layer SU204. Three first split electrodes 220-dp included in one second electrode 220 may be connected to one second trace line 220t (e.g., see FIG. 7).

The third electrode 230 may include a plurality of second split electrodes 230-dp spaced apart from each other in the first direction DR1. Each of the second split electrodes 230-dp may extend in the second direction DR2. The second split electrodes 230-dp may be spaced apart from each other in the first direction DR1. When viewed in the third direction DR3 (e.g., in a plan view), the second split electrodes 230-dp may at least partially overlap with the first patterns 211.

Referring to FIGS. 7 and 8A together, one second loop trace line 230rt2 is electrically connected to one first electrode group 230pc. One first electrode group 230pc may include two third electrodes 230. In this case, one second loop trace line 230rt2 may be electrically connected to six second split electrodes 230-dp. In this case, a degree to which the number of pads increases within the sensor layer 200 may be reduced.

The fourth electrode 240 may include a plurality of third split electrodes 240-dp spaced apart from each other in the second direction DR2. Each of the third split electrodes 240-dp may extend in the first direction DR1. Each of the third split electrodes 240-dp may include a plurality of second patterns 241, and a plurality of second bridge patterns 242 electrically connected to the second patterns 241. The second patterns 241 and the second bridge patterns 242 may be electrically connected to each other via contact holes defined in the first insulating layer 203 (e.g., see FIG. 6A). Two adjacent second patterns 241 may be spaced apart from each other, while one second split electrode 230-dp and two first bridge patterns 212 are arranged between the two adjacent second patterns 241.

In FIGS. 8A and 8B, one sensing unit SU is illustrated as including three first split electrodes 220-dp, three second split electrodes 230-dp, and three third split electrodes 240-dp, but the present disclosure is not particularly limited thereto. For example, the number of first split electrodes 220-dp, the number of second split electrodes 230-dp, and the number of third split electrodes 240-dp included in one sensing unit SU may be one, two, or not less than four.

In an embodiment of the present disclosure, a first capacitor may be defined between the first electrode 210 and the third electrode 230, and a second capacitor may be defined between the second electrode 220 and the fourth electrode 240. A first capacitance of the first capacitor and a second capacitance of the second capacitor may be adjustable by the overlap area between the first electrode 210 and the third electrode 230, and the overlap area between the second electrode 220 and the fourth electrode 240.

As the first and second capacitances increase, an amount of an induced current transferred from the third electrode 230 to the first electrode 210 may increase, and an amount of an induced current transferred from the fourth electrode 240 to the second electrode 220 may increase. Thus, as the first and second capacitances increase, a pen detection performance of the sensor layer 200 may be improved. Furthermore, the first and second capacitances may act as a load during a touch sensing. Thus, as the first and second capacitances decrease, the touch sensing performance may be improved.

In an embodiment of the present disclosure, the overlap area of the first electrode 210 and the third electrode 230 and the overlap area of the second electrode 220 and the fourth electrode 240 may be easily adjusted. Thus, the sensor layer 200 may be provided with an appropriate level of capacitance considering a desired touch sensitivity and a desired pen detection sensitivity. As a result, the electronic device 1000 (e.g., see FIG. 1A) may be provided in which both a pen sensitivity and a touch sensitivity may be improved.

In an embodiment of the present disclosure, in the second conductive layer SU204 within one sensing unit SU, an area occupied by the components included in the first electrode 210 and the second electrode 220 may be larger than an area occupied by the components included in the third electrode 230 and the fourth electrode 240. A change in a capacitance due to the first input 2000 (e.g., see FIG. 4) may be greater as a distance becomes shorter. Accordingly, the components for sensing the first input 2000 (e.g., see FIG. 4) may be arranged in a layer adjacent to a surface of the electronic device 1000 (e.g., see FIG. 1A) to have a relatively greater area. As a result, a touch performance may be improved.

Referring to FIGS. 8A, 8B, and 9, each of the first through fourth electrodes 210, 220, 230, and 240 may have a mesh structure. The mesh structure may be a structure in which a plurality of openings 200OP are defined. In FIG. 9, each of the plurality of openings 200OP is illustrated as having a circular shape with a suitable curvature (e.g., a predetermined curvature), but the present disclosure is not particularly limited thereto. For example, each of the openings 200OP may have a variety of suitable shapes, such as rectangular shape, a polygonal shape, or a non-rectangular shape.

FIG. 9 illustrates portions of the first pattern 211, the second bridge pattern 242, and the second electrode 220 disposed at (e.g., in or on) the second conductive layer SU204. The first pattern 211, the second bridge pattern 242, and the second electrode 220 may be electrically isolated from one another. For example, the first pattern 211, the second bridge pattern 242, and the second electrode 220 may be electrically isolated from each other by the first line CLa extending along a first cross direction CDR1 crossing or intersecting the first direction DR1 and the second direction DR2, and the second line CLb extending along a second cross direction CDR2 crossing or intersecting the first cross direction CDR1. One portion and another portion of a conductive layer may be spaced apart from each other with the first line CLa and the second line CLb interposed therebetween.

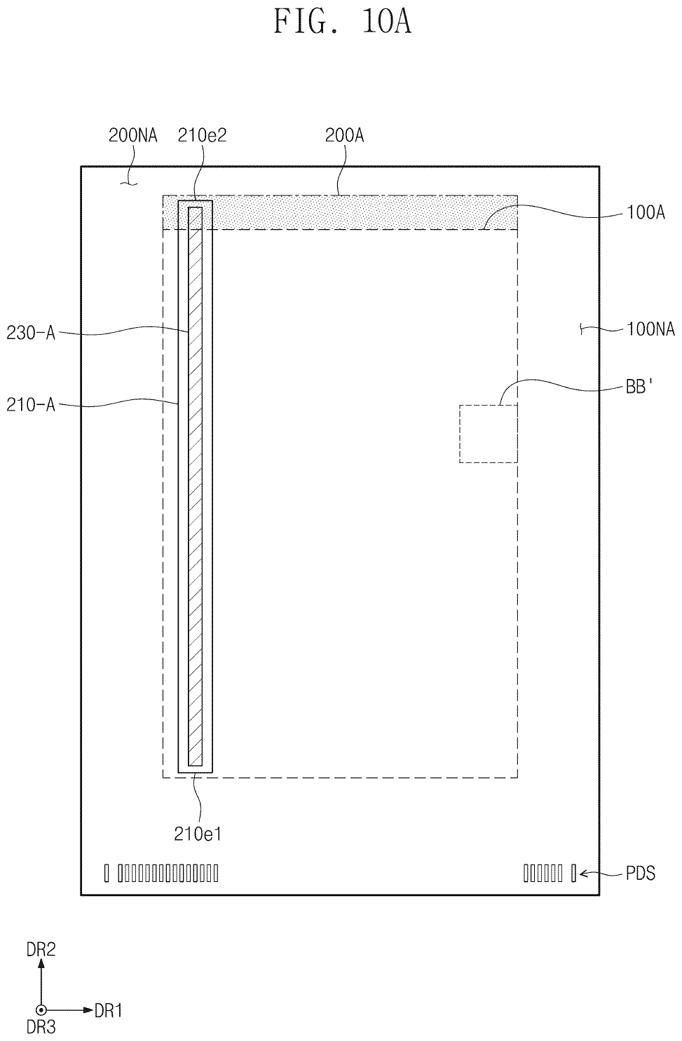

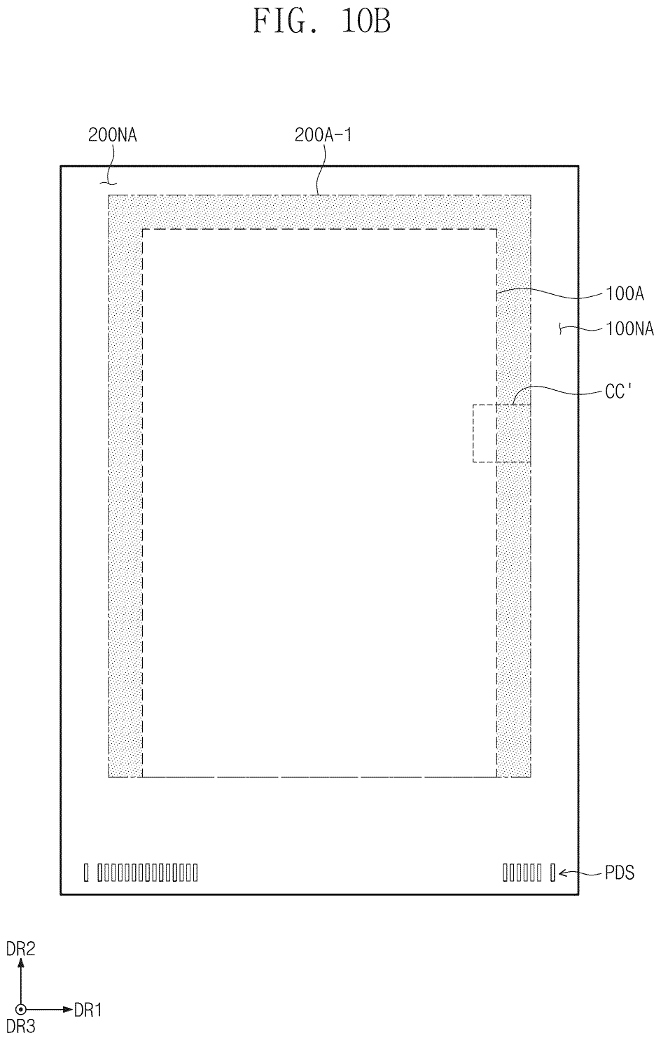

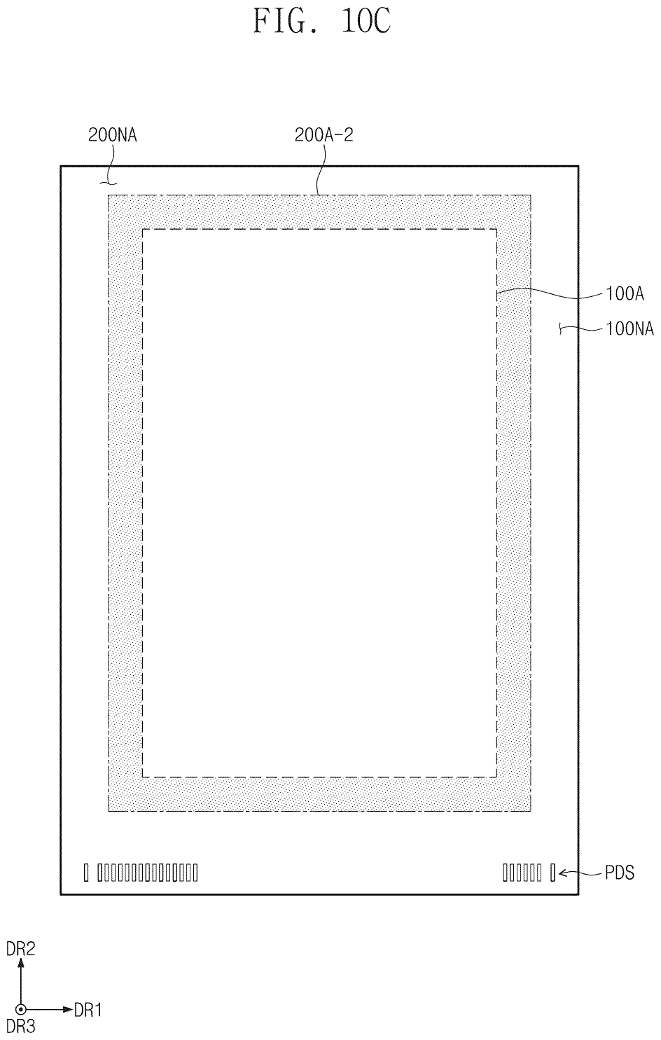

FIG. 10A is a plan view illustrating the sensing area 200A and the display area 100A according to an embodiment of the present disclosure.

Referring to FIGS. 7 and 10A, the area of the sensing area 200A may be larger than the area of the display area 100A. For example, the width of the sensing area 200A in the first direction DR1 may be equal to or substantially equal to and the width of the display area 100A in the first direction DR1, and the width of the sensing area 200A in the second direction DR2 may be larger than the width of the display area 100A in the second direction DR2.

A portion of the sensing area 200A that overlaps with the non-display area 100NA is shown with dark hatching. An additional electrode for sensing an external input may be further disposed in a portion of the sensing area 200A that is further extended than the display area 100A. As another example, the sensing unit disposed abutting a boundary between the display area 100A and the non-display area 100NA may be extended in the portion of the sensing area 200A. The extended area of the sensing unit may refer to at least a portion of the plurality of first electrodes 210, the plurality of second electrodes 220, the plurality of third electrodes 230, and the plurality of fourth electrodes 240 that have an extended shape to overlap with the non-display area 100NA.

In FIG. 10A, one first electrode 210-A of the first electrodes 210 and one third electrode 230-A of one of the third electrodes 230 are shown as examples. The first electrode 210-A and the third electrode 230-A may be lengthened in the second direction DR2, so that the area of the sensing area 200A is larger than the area of the display area 100A.

The second electrode 220 and the fourth electrode 240, which are disposed adjacent to a portion of the sensing area 200A overlapping with the non-display area 100NA, may be extended in their width directions in the portion of the sensing area 200A. For example, the width of at least one of the second electrodes 220 in the second direction DR2 and the width of at least one of the fourth electrodes 240 in second direction DR2 may be extended. As another example, at least one additional electrode extending along the first direction DR1 may be disposed in the portion of the sensing area 200A overlapping with the non-display area 100NA.

The length of the first electrode 210-A may be greater than the width of the display area 100A in the second direction DR2. The first electrode 210-A may include a first edge 210e1, and a second edge 210e2 spaced apart from the first edge 210e1 in the second direction DR2. The first edge 210e1 may be aligned with a boundary of the display area 100A and the non-display area 100NA. When the first edge 210e1 of the first electrode 210-A is aligned with the boundary, the opening 200OP (e.g., see FIG. 9) may not be defined in a region beyond the first edge 210e1.

The non-display area 100NA may be disposed with a plurality of pads PDS including the first to fifth pads PD1, PD2, PD3, PD4, and PD5 described above with reference to FIG. 7. The first edge 210e1 may be arranged between the plurality of pads PDS and the second edge 210e2. In other words, according to an embodiment of the present disclosure, the sensing area 200A may not be extended in a region between the display area 100A and the plurality of pads PDS, where wires may be concentrated.

FIG. 10B is a plan view illustrating a sensing area 200A-1 and the display area 100A according to an embodiment of the present disclosure.

Referring to FIG. 7 and FIG. 10B, the area of the sensing area 200A-1 may be larger than the area of the display area 100A. For example, the width of the sensing area 200A-1 in the first direction DR1 may be larger than the width of the display area 100A in the first direction DR1, and the width of the sensing area 200A-1 in the second direction DR2 may be larger than the width of the display area 100A in the second direction DR2.

A portion of the sensing area 200A-1 that overlaps with the non-display area 100NA is shown with dark hatching. An additional electrode may be further disposed in the sensing area 200A that is further extended than the display area 100A, and the sensing unit disposed abutting a boundary between the display area 100A and the non-display area 100NA may be extended.

In an embodiment of the present disclosure, the sensing area 200A-1 may be extended in a remaining boundary between the display area 100A and the non-display area 100NA, except for in a region between the display area 100A and the plurality of pads PDS where the trace lines described above with reference to FIG. 7 are concentrated. For example, the sensing area 200A-1 may be extended in the upper, left, and right directions of the display area 100A.

FIG. 10C is a plan view illustrating a sensing area 200A-2 and the display area 100A according to an embodiment of the present disclosure.

Referring to FIGS. 7 and 10C, the area of the sensing area 200A-2 may be larger than the area of the display area 100A. For example, the width of the sensing area 200A-2 in the first direction DR1 may be larger than the width of the display area 100A in the first direction DR1, and the width of the sensing area 200A-2 in the second direction DR2 may be larger than the width of the display area 100A in the second direction DR2.

In an embodiment of the present disclosure, the sensing area 200A-2 may be extended in all of the upper, lower, left, and right directions of the display area 100A. A portion of the sensing area 200A-2 that overlaps with the non-display area 100NA is shown with dark hatching. An additional electrode may be further disposed in the sensing area 200A-2 that is further extended than the display area 100A, and the sensing unit disposed abutting a boundary between the display area 100A and the non-display area 100NA may be extended.

According to the embodiments illustrated in FIGS. 10A, 10B, and 10C, the area of each of the sensing areas 200A, 200A-1, and 200A-2 may be wider than the area of the display area 100A. In other words, a portion of each of the sensing areas 200A, 200A-1, and 200A-2 may overlap with the non-display area 100NA. In this case, even when an input occurs adjacent to a boundary between the display area 100A and the non-display area 100NA, a signal may be sufficiently recognized, because the sensing area 200A overlaps with a portion of the non-display area 100NA. Therefore, an accuracy of coordinates of a touch input onto the outskirt may be improved.

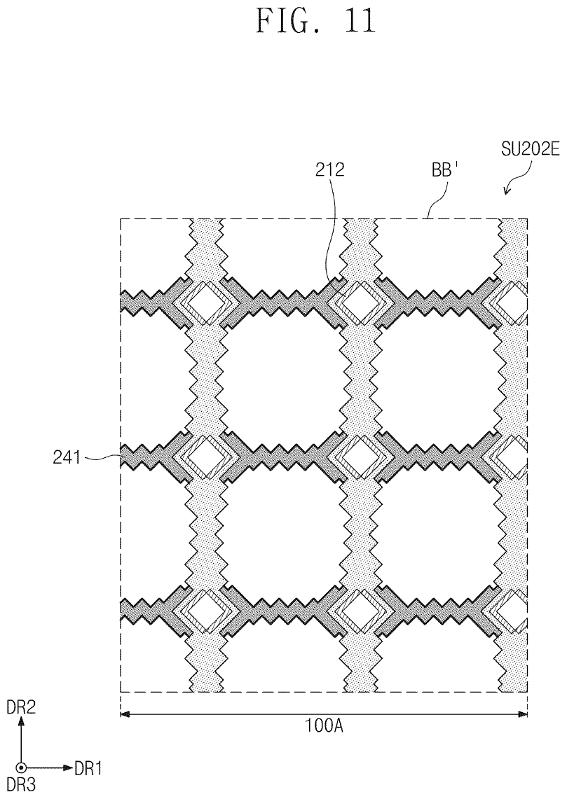

FIG. 11 is a plan view illustrating a first conductive layer SU202E of a sensing unit arranged in the region BB′ illustrated in FIG. 10A.

Referring to FIG. 10A and FIG. 11, the first conductive layer SU202E may be included in a sensing unit that is adjacent to a boundary between the sensing area 200A and the peripheral area 200NA. For example, FIG. 8A may illustrate the first conductive layer SU202 of the sensing unit SU that is spaced from the boundary between the sensing area 200A and the peripheral area 200NA.

Referring to the first conductive layer SU202E illustrated in FIG. 11, the first conductive layer SU202E may have a shape in which a portion on the right side thereof is removed when compared to the shape of the first conductive layer SU202 illustrated in FIG. 8A. In this case, the center of a current path of a sensing unit adjacent to the boundary between the sensing area 200A and the peripheral area 200NA may be shifted to be closer to the boundary. In this case, when the sensor driver 200C (e.g., see FIG. 5) obtains a signal by differentiating signals received from two electrodes, the intensity of the signal resulting from the differentiation may increase, resulting in an improvement in the sensitivity of the signal.

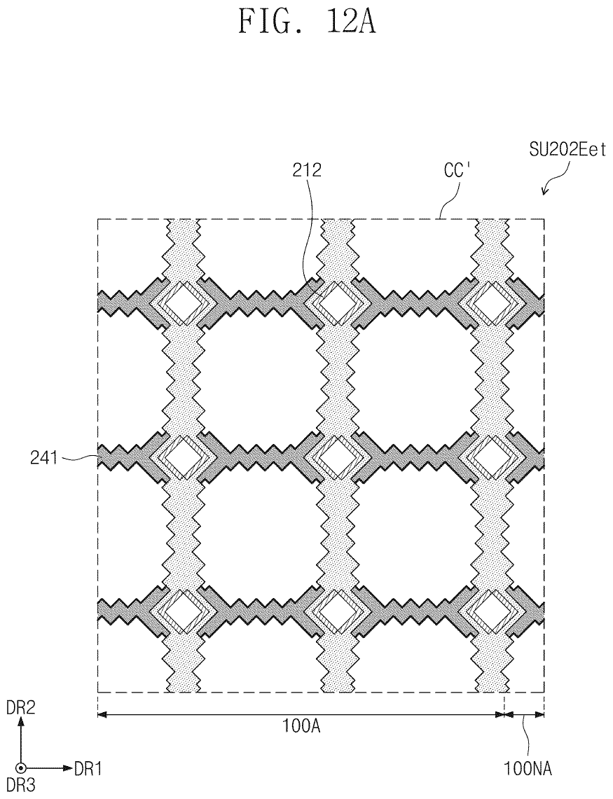

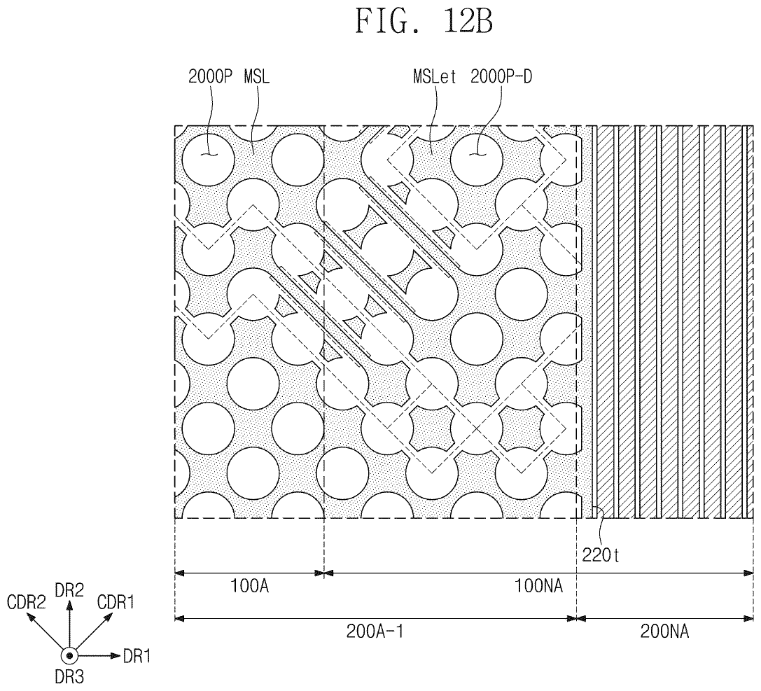

FIG. 12A is a plan view illustrating a first conductive layer SU202Eet of a sensing unit arranged in the region CC′ area illustrated in FIG. 10B. FIG. 12B is a plan view showing a portion of a second conductive layer arranged in the region CC′ illustrated in FIG. 10B.

Referring to FIG. 10B and FIGS. 12A and 12B, the first conductive layer SU202Eet may be included in a sensing unit adjacent to a boundary between the sensing area 200A-1 and the peripheral area 200NA. The first conductive layer SU202Eet may have a structure that is further extended to the right when compared to the first conductive layer SU202E illustrated in FIG. 11.

Therefore, the first conductive layer SU202Eet may include a portion overlapping with the display area 100A, and a portion overlapping with the non-display area 100NA. The first conductive layer SU202E illustrated in FIG. 11 may correspond to a portion of the first conductive layer SU202Eet that overlaps with the display area 100A illustrated in FIG. 12A.

Referring to FIG. 12B, an enlarged view of a portion of the second conductive layer 204 (e.g., see FIG. 6A) is shown. A mesh structure MSL of the second conductive layer 204 may overlap with the non-display area 100NA. Therefore, the mesh structure MSL may include an extended portion MSLet that overlaps with the non-display area 100NA, and a plurality of openings 200OP-D may be defined in the extended portion MSLet. For example, the opening 200OP overlapping with the display area 100A may overlap with the emission area PXA illustrated in FIG. 6A. On the other hand, the opening 200OP-D overlapping with the non-display area 100NA, which is an area where light is not output, may not overlap with the emission area PXA.

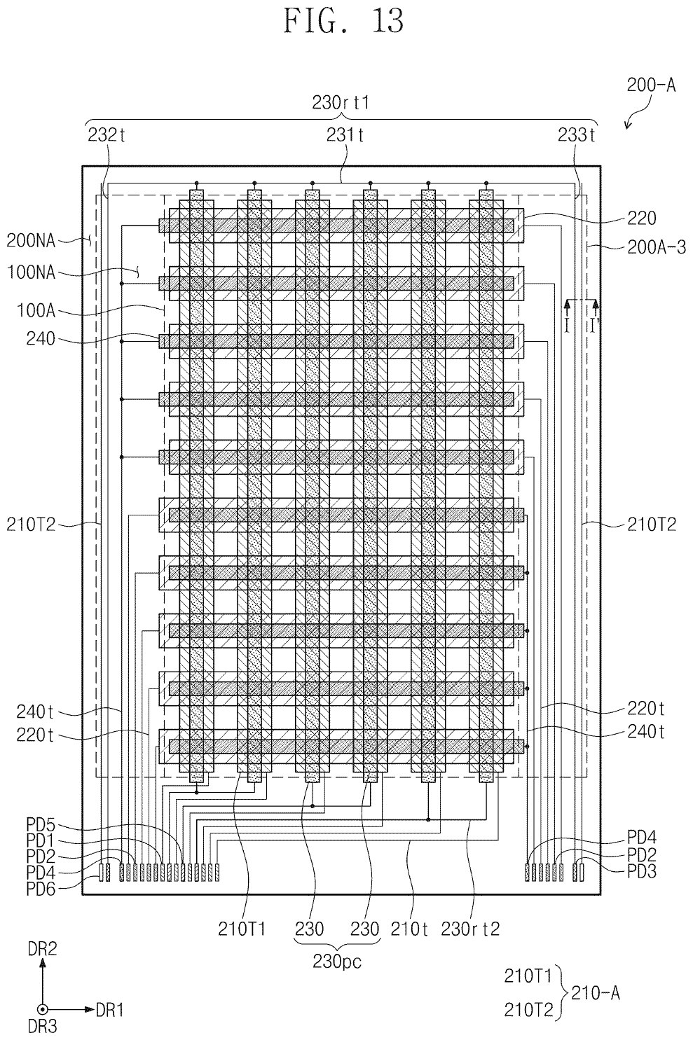

FIG. 13 is a plan view of a sensor layer 200-A according to an embodiment of the present disclosure. In FIG. 13, the same reference numerals are assigned to the same or substantially the same components as those described above with reference to FIG. 7, and thus, redundant description thereof may not be repeated hereinafter.

Referring to FIG. 4 and FIG. 13, a sensing area 200A-3 and the peripheral area 200NA adjacent to the sensing area 200A-3 may be defined in the sensor layer 200-A.

The sensor layer 200-A may include a plurality of first electrodes 210-A, the plurality of second electrodes 220, the plurality of third electrodes 230, and the plurality of fourth electrodes 240, which are disposed in the sensing area 200A-3.

The first electrodes 210-A may include first type electrodes 210T1 arranged in a region overlapping with the display area 100A, and second type electrodes 210T2 arranged in a region overlapping with the non-display area 100NA.

In FIG. 13, six first type electrodes 210T1 and two second type electrodes 210T2 are illustrated as examples. One second type electrode 210T2 and another second type electrode 210T2 may be spaced apart from each other in the first direction DR1 with the first type electrodes 210T1 interposed therebetween.

The first type electrodes 210T1 may have a mesh structure in which a plurality of openings are defined, because the first type electrodes 210T1 overlap with the emission area PXA (e.g., see FIG. 6A). For example, the first type electrodes 210T1 may have a mesh structure in which the openings 200OP as illustrated in FIG. 9 are defined. The second type electrodes 210T2 may overlap with the non-display area 100NA. Therefore, the shape of the second type electrodes 210T2 may be different from the shape of the first type electrodes 210T1. For example, the second type electrodes 210T2 may have a solid structure in which no opening is defined.

The second type electrode 210T2 may be adjacent to the first loop trace line 230rt1. For example, one second type electrode 210T2 may be adjacent to the second line portion 232t of the first loop trace line 230rt1, and another second type electrode 210T2 may be adjacent to the third line portion 233t of the first loop trace line 230rt1.

The second type electrodes 210T2 may be arranged in the non-display area 100NA, and may be connected to sixth pads PD6 in a one-to-one correspondence. Therefore, the second type electrodes 210T2 may transmit a signal to the sensor driver 200C (e.g., see FIG. 5), or may receive a signal. In other words, each of the second type electrodes 210T2 may function as an independent electrode, and may form an additional channel. The second type electrodes 210T2 may be used in a pen signal sensing, and may be grounded or used as auxiliary electrodes for a self-capacitance driving in a touch driving.

The sensor driver 200C may receive or may detect a signal provided from a pen, for example, such as an induced current, from the second type electrodes 210T2. Therefore, even when the pen is located at the boundary between the display area 100A and the non-display area 100NA, or located in the non-display area 100NA, the sensor driver 200C may receive a signal provided from the pen. In other words, by utilizing the second type electrodes 210T2 to detect the coordinates of a pen located adjacent to the edge of the display area 100A, the accuracy of the coordinates of the pen may be improved.

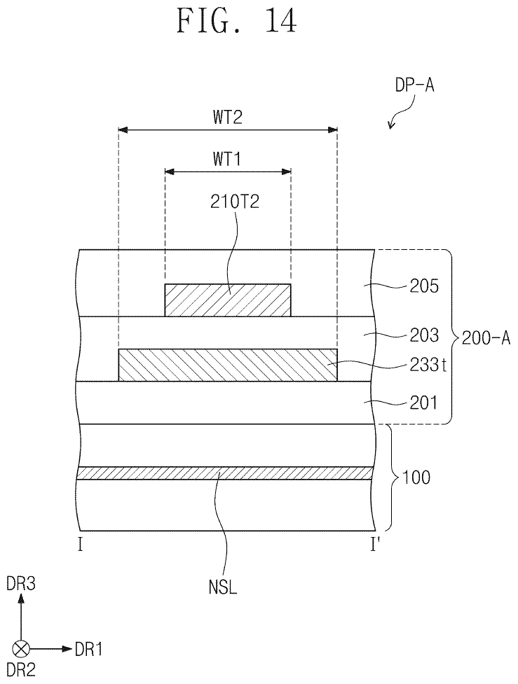

FIG. 14 is a cross-sectional view of a display panel DP-A including a portion taken along the line I-I′ illustrated in FIG. 13 according to an embodiment of the present disclosure.

Referring to FIGS. 13 and 14, the display panel DP-A may include the display layer 100 and the sensor layer 200-A. The sensor layer 200-A may be arranged on the display layer 100.

The display layer 100 may further include a noise shielding layer NSL. The noise shielding layer NSL may be provided with a signal that is the same or substantially the same as that provided to the second electrode CE (e.g., see FIG. 6A), or may be provided with a constant or substantially constant voltage. As another example, the noise shielding layer NSL may be grounded. The noise shielding layer NSL may be formed concurrently (e.g., simultaneously or substantially simultaneously) with the same material as that of the first electrode AE illustrated in FIG. 6A, may be formed concurrently (e.g., simultaneously or substantially simultaneously) with the same material as that of the second electrode CE, or may be formed concurrently (e.g., simultaneously or substantially simultaneously) with the same material as that of the second connection electrode CNE2. However, the present disclosure is not particularly limited thereto. For example, in another embodiment, the noise shielding layer NSL may be omitted as needed or desired.

The second type electrode 210T2 may overlap with the first loop trace line 230rt1. The first loop trace line 230rt1 may be arranged between the second type electrode 210T2 and the display layer 100. In FIG. 14, the third line portion 233t of the first loop trace line 230rt1 is illustrated as an example. In an embodiment of the present disclosure, a first width WT1 of the second type electrode 210T2 may be smaller than a second width WT2 of the third line portion 233t. However, the present disclosure is not particularly limited thereto. For example, the first width WT1 may be the same or substantially the same as the second width WT2, or the first width WT1 may be larger than the second width WT2.

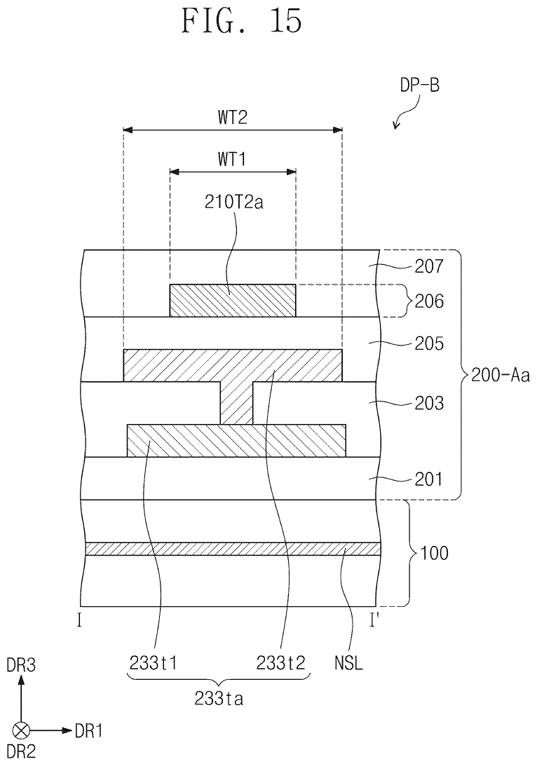

FIG. 15 is a cross-sectional view of a display panel DP-B including a portion taken along the line I-I′ illustrated in FIG. 13 according to an embodiment of the present disclosure. In FIG. 15, the same reference numerals are assigned to the same or substantially the same components as those described above with reference to FIG. 14, and thus, redundant description thereof may not be repeated hereinafter.

Referring to FIGS. 13 and 15, the display panel DP-B may include the display layer 100 and a sensor layer 200-Aa. The sensor layer 200-Aa may further include a third conductive layer 206 disposed on the second insulating layer 205, and a third insulating layer 207 disposed on the second insulating layer 205 and covering the third conductive layer 206, when compared to the sensor layer 200 described above with reference to FIG. 6A. In other words, the sensor layer 200-Aa may include three conductive layers. In an embodiment of the present disclosure, one of the first loop trace line 230rt1 or a second type electrode 210T2a may include a plurality of conductive layers.

For example, referring to the third line portion 233ta of the first loop trace line 230rt1 illustrated in FIG. 15, the sensor layer 200-Aa may include a first conductive line 233t1, and a second conductive line 233t2 disposed at (e.g., in or on) a different layer from that of the first conductive line 233t1. The first conductive line 233t1 and the second conductive line 23312 may be electrically connected to each other. As the first loop trace line 230rt1 is implemented with a plurality of layers, a resistance of the first loop trace line 230rt1 may be reduced, and as a result, a charging performance in the outskirt may be enhanced.

The second type electrode 210T2a may be disposed on the second insulating layer 205. For example, the second type electrode 210T2a may be included in the third conductive layer 206. The third insulating layer 207 may cover the second type electrode 210T2a.

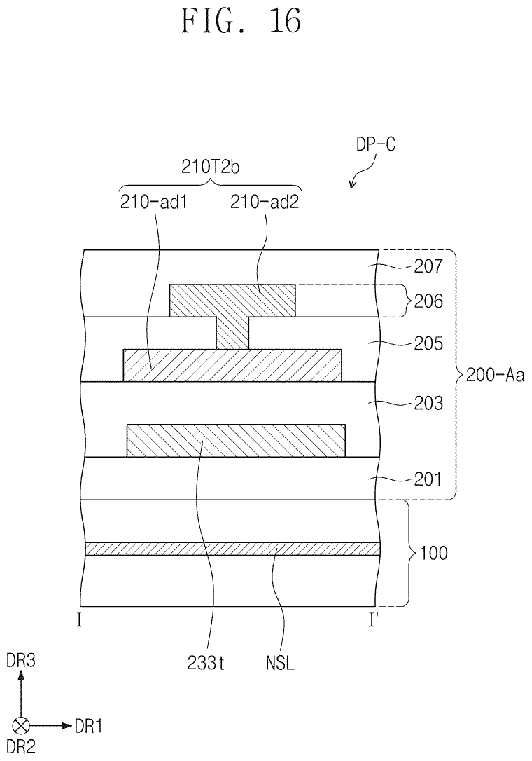

FIG. 16 is a cross-sectional view of a display panel DP-C including a portion taken along the line I-I′ illustrated in FIG. 13 according to an embodiment of the present disclosure. In FIG. 16, the same reference numerals are assigned to the same or substantially the same components as those described above with reference to FIGS. 14 and 15, and thus, redundant description thereof may not be repeated hereinafter.

Referring to FIGS. 13 and 16, one of the first loop trace line 230rt1 or a second type electrode 210T2b may include a plurality of conductive layers.

For example, the second type electrode 210T2b may include a first conductive line 210-ad1, and a second conductive line 210-ad2 arranged at (e.g., in or on) a different layer from that of the first conductive line 210-ad1. The first conductive line 210-ad1 and the second conductive line 210-ad2 may be electrically connected to each other. As the second type electrode 210T2b is implemented with a plurality of layers, a resistance of the second type electrode 210T2b may be reduced, and as a result, a sensing performance in the outskirt may be enhanced.

The second conductive line 210-ad2 may be arranged on the second insulating layer 205. For example, the second conductive line 210-ad2 may be included in the third conductive layer 206. The third insulating layer 207 may cover the second conductive line 210-ad2.

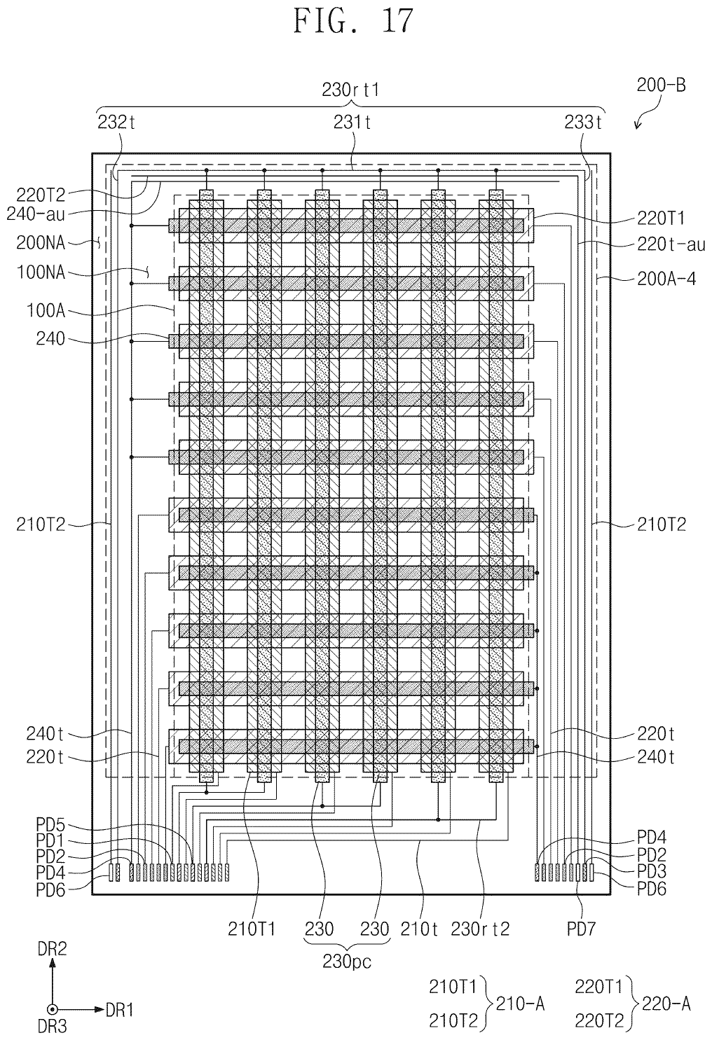

FIG. 17 is a plan view of a sensor layer 200-B according to an embodiment of the present disclosure. In FIG. 17, the same reference numerals are assigned to the same or substantially the same components as those described above with reference to FIGS. 7 and 13, and thus, redundant description thereof may not be repeated hereinafter.

Referring to FIGS. 4 and 17, a sensing area 200A-4 and the peripheral area 200NA adjacent to the sensing area 200A-4 may be defined in the sensor layer 200-B.

The sensor layer 200-B may include the plurality of first electrodes 210-A, a plurality of second electrodes 220-A, the plurality of third electrodes 230, and the plurality of fourth electrodes 240, which are disposed in the sensing area 200A-4.

The first electrodes 210-A may include the first type electrodes 210T1 arranged in an area overlapping with the display area 100A, and the second type electrodes 210T2 arranged in an area overlapping with the non-display area 100NA. The second electrodes 220-A may include first type electrodes 220T1 (hereinafter referred to as third type electrodes) arranged in a region overlapping with the display area 100A, and second type electrodes 220T2 (hereinafter referred to as fourth type electrodes) arranged in an area overlapping with the non-display area 100NA.

In addition, the sensor layer 200-B may further include an auxiliary electrode 240-au and an auxiliary trace line 220t-au. The auxiliary electrode 240-au may be electrically connected to the group trace line 240t, and may overlap with the non-display area 100NA. The auxiliary trace line 220t-au may be electrically connected to the fourth type electrode 220T2, and may overlap with the non-display area 100NA. The auxiliary trace line 220t-au and the group trace line 240t may be spaced apart from each other with the display area 100A interposed therebetween. The fourth type electrode 220T2 may be arranged in the non-display area 100NA, and may be connected to a seventh pad PD7. Therefore, the fourth type electrode 220T2 may transmit a signal to the sensor driver 200C (e.g., see FIG. 5), or may receive a signal. In other words, the fourth type electrode 220T2 may function as an independent electrode, and may form an additional channel. The fourth type electrode 220T2 may be used when sensing a pen signal, and may be grounded or utilized as an auxiliary electrode for driving a self-capacitance when driving a touch.

The sensor driver 200C may receive or detect a signal, for example, such as an induced current, provided from a pen through the second type electrodes 210T2 and the fourth type electrode 220T2. Therefore, even when the pen is located at a boundary between the display area 100A and the non-display area 100NA or located in the non-display area 100NA, the sensor driver 200C may receive a signal provided from the pen. In other words, by utilizing the second type electrodes 210T2 and the fourth type electrode 220T2, the pen coordinate accuracy may be improved by detecting the coordinates of the pen located adjacent to an edge of the display area 100A.

FIG. 18 is a plan view of a sensor layer 200-C according to an embodiment of the present disclosure. In FIG. 18, the same reference numerals are assigned to the same or substantially the same components as those described above with reference to FIG. 7, and thus, redundant description thereof may not be repeated hereinafter.

Referring to FIG. 18, a sensing area 200A-5 and the peripheral area 200NA adjacent to the sensing area 200A-5 may be defined in the sensor layer 200-C.

The sensor layer 200-C may include a plurality of first electrodes 210-Aa, the plurality of second electrodes 220, the plurality of third electrodes 230, and the plurality of fourth electrodes 240, which are disposed in the sensing area 200A-5.

The first electrodes 210-Aa may include the first type electrodes 210T1 arranged in an area overlapping with the display area 100A, and second type electrodes 210T2a arranged in an area overlapping with the non-display area 100NA.

The second type electrodes 210T2a may overlap with the non-display area 100NA. Therefore, the shape of the second type electrodes 210T2a may be different from the shape of the first type electrodes 210T1. For example, each of the first type electrodes 210T1 may have a mesh structure in which an opening is defined, and the second type electrodes 210T2a may have a solid structure in which no opening is defined.

According to an embodiment of the present disclosure, each of the second type electrodes 210T2a may have a loop shape. Each of the second type electrodes 210T2a may be connected to a corresponding first loop pad PD61 at one end thereof, and may be connected to a corresponding second loop pad PD61 at another end (e.g., an opposite end) thereof.

In an embodiment of the present disclosure, an induced current may flow through each of the second type electrodes 210T2a due to a magnetic field emitted from the pen, and the induced current may be transmitted to the sensor driver 200C (e.g., see FIG. 5) as a reception signal. Therefore, even when the pen is located at a boundary between the display area 100A and the non-display area 100NA or located in the non-display area 100NA, the sensor driver 200C may receive a signal provided from the pen. In other words, by utilizing the second type electrodes 210T2a to detect the coordinates of the pen located adjacent to an edge of the display area 100A, the pen coordinate accuracy may be improved.

Furthermore, in an embodiment of the present disclosure, the second type electrodes 210T2a may also function as charging electrodes. In this case, a first signal may be provided to the first loop pad PD61, and a second signal having a phase difference of 180 degrees from that of the first signal may be provided to the second loop pad PD61 to form a magnetic field.

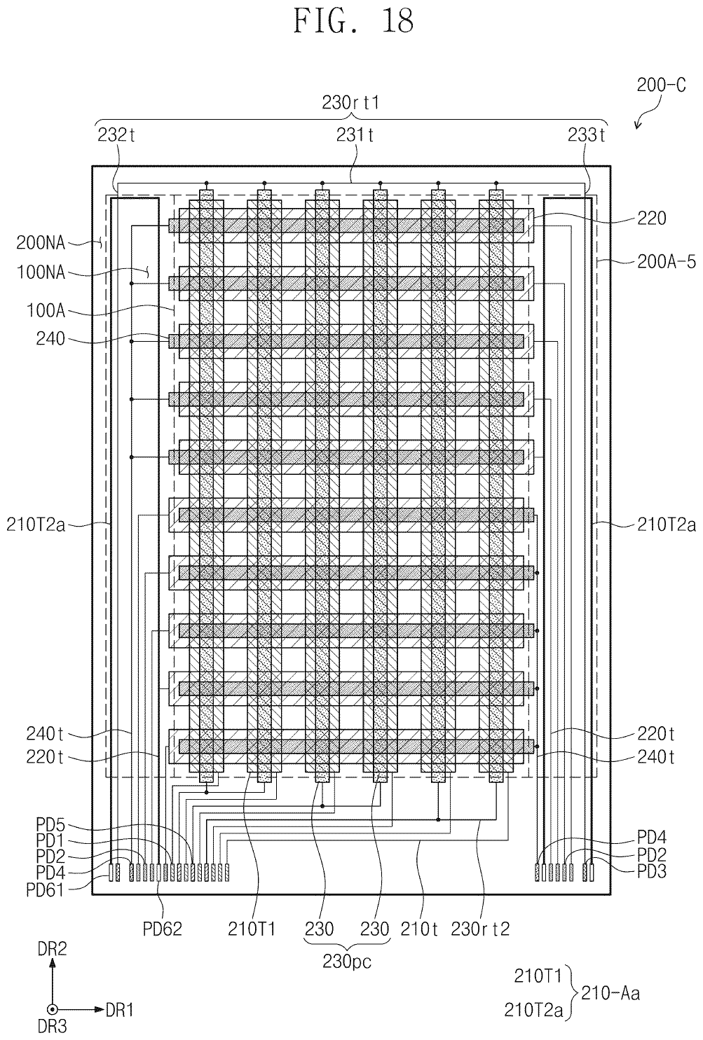

FIG. 19 is a diagram illustrating an operation of the sensor driver 200C according to an embodiment of the present disclosure.

Referring to FIGS. 5 and 19, the sensor driver 200C may be selectively operated in one of a first operating mode DMD1, a second operating mode DMD2, and a third operating mode DMD3.

The first operating mode DMD1 may be referred to as a “touch and pen standby mode”. The second operating mode DMD2 may be referred to as a “touch activation and pen standby mode”. The third operating mode DMD3 may be referred to as a “pen activation mode”. The first operating mode DMD1 may be a mode for waiting for the first input 2000 and the second input 3000. The second operating mode DMD2 may be a mode for sensing the first input 2000, and waiting for the second input 3000. The third operating mode DMD3 may be a mode for sensing the second input 3000.

In an embodiment of the present disclosure, the sensor driver 200C may be first driven in the first operating mode DMD1. When the first input 2000 is sensed in the first operating mode DMD1, the operating mode of the sensor driver 200C may be switched (e.g., changed) to the second operating mode DMD2. As another example, when the second input 3000 is sensed in the first operating mode DMD1, the operating mode of the sensor driver 200C may be switched (e.g., changed) to the third operating mode DMD3.

In an embodiment of the present disclosure, when the second input 3000 is sensed in the second operating mode DMD2, an operating mode of the sensor driver 200C may be switched to the third operating mode DMD3. When the first input 2000 is terminated (e.g., not detected) in the second operating mode DMD2, an operating mode of the sensor driver 200C may be switched to the first operating mode DMD1. When the second input 3000 is terminated (e.g., not detected) in the third operating mode DMD3, an operating mode of the sensor driver 200C may be switched to the first operating mode DMD1.

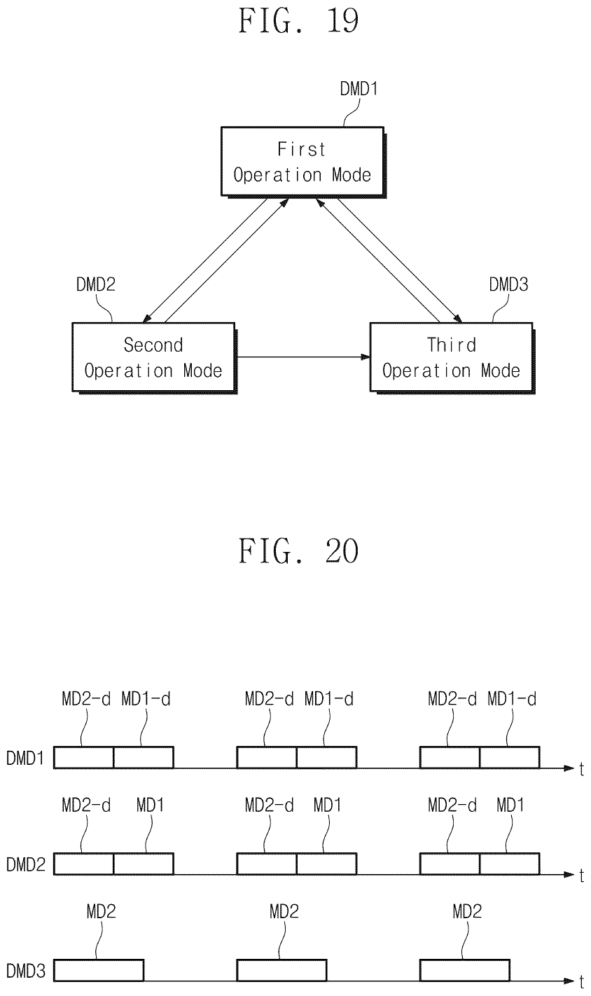

FIG. 20 is a diagram illustrating an operation of the sensor driver 200C according to an embodiment of the present disclosure.

Referring to FIGS. 5, 19, and 20, operations in the first to third operating modes DMD1, DMD2, and DMD3 over time (t) are illustrated as an example.

In the first operating mode DMD1, the sensor driver 200C may be repeatedly driven in a second mode MD2-d and a first mode MD1-d. During the second mode MD2-d, the sensor layer 200 may be scanned and driven to detect the second input 3000. During the first mode MD1-d, the sensor layer 200 may be scanned and driven to detect the first input 2000. As an example, the sensor driver 200C may operate in the first mode MD1-d immediately after (e.g., to be continuous to) the second mode MD2-d as illustrated in FIG. 20, but the order of the first mode MD1-d and the second mode MD2-d is not limited thereto.

In the second operating mode DMD2, the sensor driver 200C may be repeatedly driven in the second mode MD2-d and a first mode MD1. During the second mode MD2-d, the sensor layer 200 may be scanned and driven to detect the second input 3000. During the first mode MD1, the sensor layer 200 may be scanned and driven to detect coordinates of the first input 2000.

In the third operating mode DMD3, the sensor driver 200C may operate in a second mode MD2. During the second mode MD2, the sensor layer 200 may be scanned and driven to detect coordinates corresponding to the second input 3000. In the third operating mode DMD3, the sensor driver 200C may not operate in the first mode MD1-d or MD1 until the second input 3000 is released (e.g., is not sensed).

Referring to FIG. 7 together, in the first mode MD1-d and the first mode MD1, all of the third electrodes 230 and the fourth electrodes 240 may be grounded, or a constant or substantially constant voltage may be applied to all of the third electrodes 230 and the fourth electrodes 240. In the first mode MD1-d and the first mode MD1, the third electrodes 230 and the fourth electrodes 240 may be all floated (e.g., electrically floated). As another example, in the first mode MD1-d and the first mode MD1, a signal having the same phase as that of a transmission signal provided to the first electrodes 210 may be applied to the third electrodes 230 and the fourth electrodes 240. In this case, a touch noise may be prevented or substantially prevented from entering through the third electrodes 230 and the fourth electrodes 240.

In the second mode MD2-d and the second mode MD2, a first end of each of the third electrodes 230 and the fourth electrodes 240 may be floated. Also, in the second mode MD2-d and the second mode MD2, a second end of each of the third electrodes 230 and the fourth electrodes 240 may be grounded or floated. Accordingly, a sensing signal may be maximally compensated for by the coupling between the first electrodes 210 and the third electrodes 230, and the coupling between the second electrodes 220 and the fourth electrodes 240.

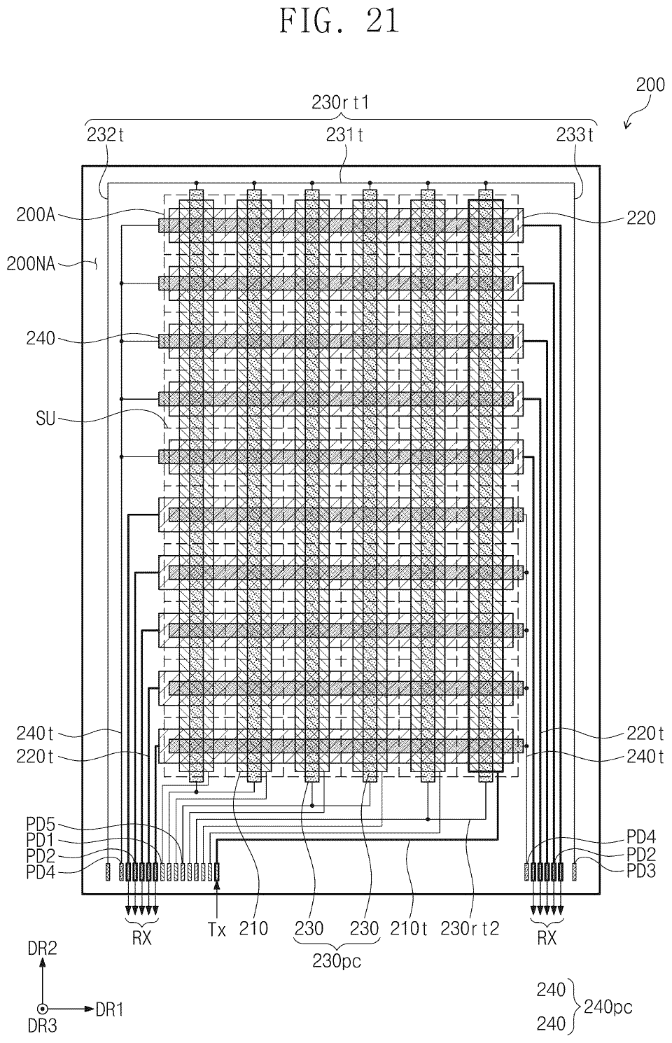

FIG. 21 is a diagram illustrating a first mode according to an embodiment of the present disclosure.

Referring to FIGS. 5, 20, and 21, the first mode MD1-d of the first operating mode DMD1 and the first mode MD1 of the second operating mode DMD2 may include a mutual capacitance detection mode. FIG. 21 is a diagram illustrating the mutual capacitance detection mode in the first mode MD1-d of the first operating mode DMD1 and the first mode MD1 of the second operating mode DMD2.

In the mutual capacitance detection mode, the sensor driver 200C may sequentially provide a transmission signal TX to the first electrodes 210, and may detect coordinates for the first input 2000 by using a reception signal RX detected through the second electrodes 220. For example, the sensor driver 200C may calculate input coordinates by sensing changes in a mutual capacitance between the first electrodes 210 and the second electrodes 220.

An example in which the transmission signal TX is provided to one first electrode 210 and the reception signal RX is output from one second electrode 220 is illustrated in FIG. 21. The sensor driver 200C may detect input coordinates of the first input 2000 by sensing a change in a capacitance between each of the first electrodes 210 and each of the second electrodes 220.

In another embodiment of the present disclosure, at least one of the first mode MD1-d of the first operating mode DMD1 or the first mode MD1 of the second operating mode DMD2 may further include a self-capacitance detection mode. In the self-capacitance detection mode, the sensor driver 200C may output driving signals to the first electrodes 210 and the second electrodes 220, and may calculate input coordinates by sensing changes in a capacitance in the first electrodes 210 and the second electrodes 220.

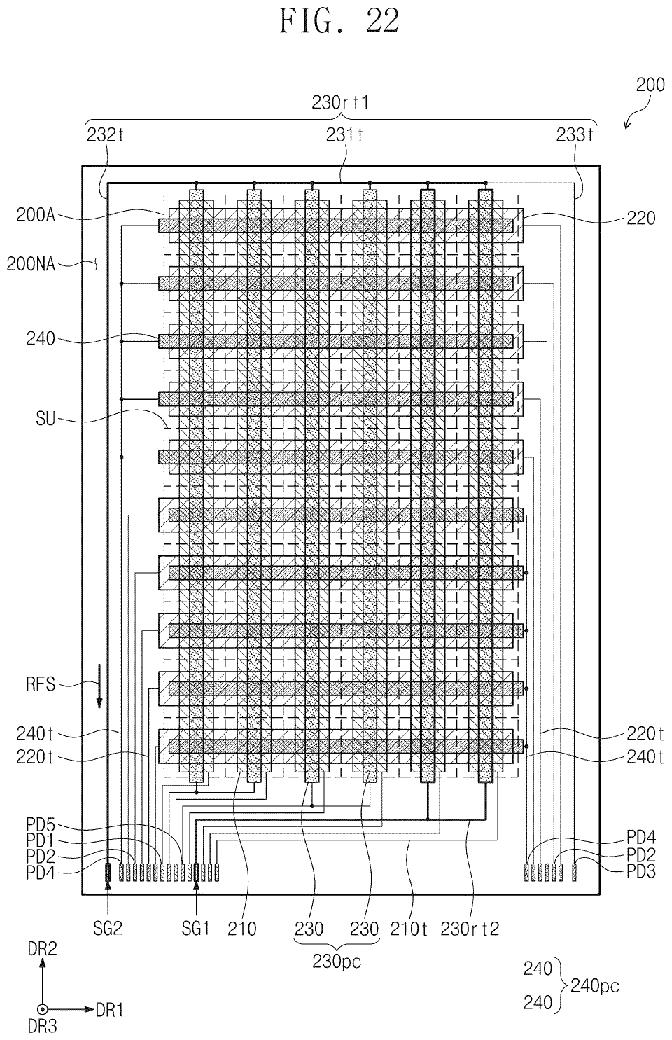

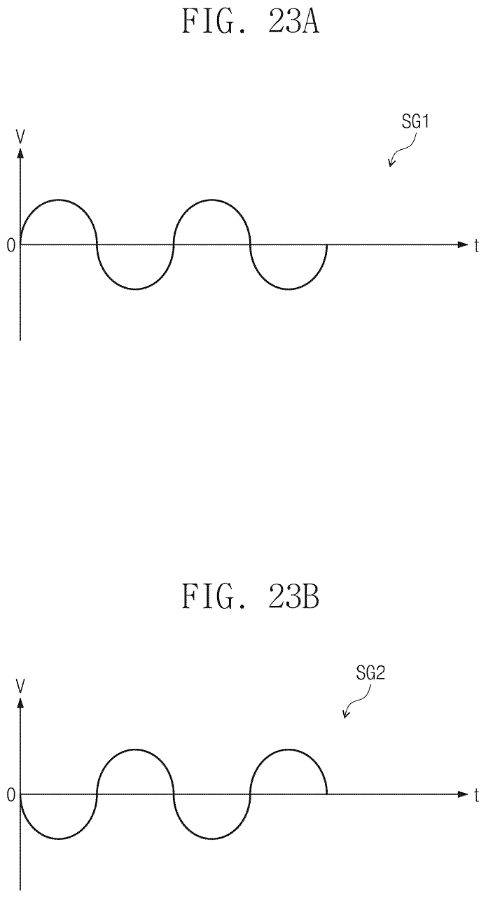

FIG. 22 is a diagram illustrating a second mode according to an embodiment of the present disclosure. For example, FIG. 22 may illustrate a charging driving mode of the second mode. FIG. 23A is a graph showing a waveform of a first signal SG1 according to an embodiment of the present disclosure. FIG. 23B is a graph showing a waveform of a second signal SG2 according to an embodiment of the present disclosure.

Referring to FIGS. 22, 23A, and 23B, the second mode MD2 may include the charging driving mode. The charging driving mode may include a searching charging driving mode and a tracking charging driving mode.

The searching charging driving mode may be a driving mode before a location of the pen is sensed. Accordingly, the first signal SG1 or the second signal SG2 may be sequentially provided to all channels included in the sensor layer 200. In other words, the entire area of the sensor layer 200 may be sequentially scanned in the searching charging driving mode. When the pen PN is sensed in the searching charging driving mode, the sensor layer 200 may be driven for tracking charging. For example, in the tracking charging driving mode, the sensor driver 200C may sequentially output the first signal SG1 and the second signal SG2 to an area overlapping with a point where the pen PN is sensed, and not to the entire area of the sensor layer 200.

In the charging driving mode, the sensor driver 200C may apply the first signal SG1 to one of the third pads PD3 or the fifth pads PD5, and may apply the second signal SG2 to the other pad. The second signal SG2 may be an inverse signal of the first signal SG1. For example, the first signal SG1 may be a sinusoidal signal.

Because the first signal SG1 and the second signal SG2 are applied to at least two pads, a current RFS may have a current path through one pad to the other pad. Also, because the first signal SG1 and the second signal SG2 are sinusoidal signals having phases that are opposite to each other, a direction of the current RFS may periodically change. In an embodiment of the present disclosure, the first signal SG1 and the second signal SG2 may be square wave signals having an inverse-phase relationship to each other.

When the first signal SG1 and the second signal SG2 have an inverse-phase relationship with each other, a noise caused by the first signal SG1 in the display layer 100 (e.g., see FIG. 4) may be canceled out with a noise caused by the second signal SG2. Accordingly, a flicker may not occur in the display layer 100, and a display quality of the display layer 100 may be improved.

In an embodiment of the present disclosure, the first signal SG1 may be a sinusoidal signal. However, the present disclosure is not limited thereto, and the first signal SG1 may be a square wave signal. In some embodiments, the second signal SG2 may have a suitable constant voltage (e.g., a predetermined constant voltage). For example, the second signal SG2 may be a ground voltage. In other words, a pad to which the second signal SG2 is applied may be regarded as being grounded. In this case, the current RFS may flow from one pad to the other pad. Also, because the first signal SG1 is a sinusoidal wave signal or square wave signal, even when the other pad is grounded, the direction of the current RFS may change periodically.

Referring to FIG. 22, the second signal SG2 is provided to one third pad PD3 connected to one first loop trace line 230rt1, and the first signal SG1 is provided to one fifth pad PD5 connected to the third electrode 230. The current RFS may flow through a current path defined by the fifth pad PD5, the second loop trace line 230rt2 connected to the fifth pad PD5, the third electrode 230, a portion of the first loop trace line 230rt1 connected to the third pad PD3, and the third pad PD3. The current path may have the form of a coil. Accordingly, in the charging driving mode of the second mode, the resonant circuit of the pen PN may be charged by the current path.

According to some embodiments of the present disclosure, a current path of a loop coil pattern may be implemented by the components included in the sensor layer 200. Accordingly, the electronic device 1000 (e.g., refer to FIG. 1A) may charge the pen PN by using the sensor layer 200. In other words, because a configuration having a coil for charging the pen PN may not be separately added, an increase in the thickness of the electronic device 1000, an increase in the weight of the electronic device 1000, and a decrease in flexibility of the electronic device 1000 may not occur.

In the charging driving mode, the first electrodes 210, the second electrodes 220, and the fourth electrodes 240 may be grounded, may be provided with a constant or substantially constant voltage, or may be electrically floated. In more detail, the first electrodes 210, the second electrodes 220, and the fourth electrodes 240 may be floated. In this case, the current RFS may not flow to the first electrodes 210, the second electrodes 220, and the fourth electrodes 240.

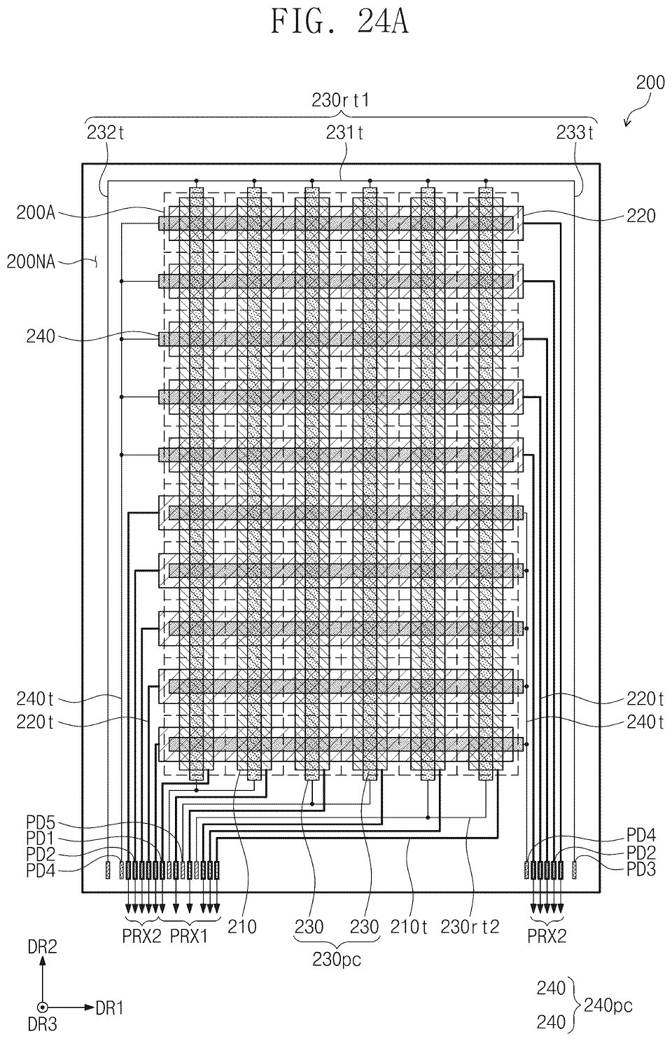

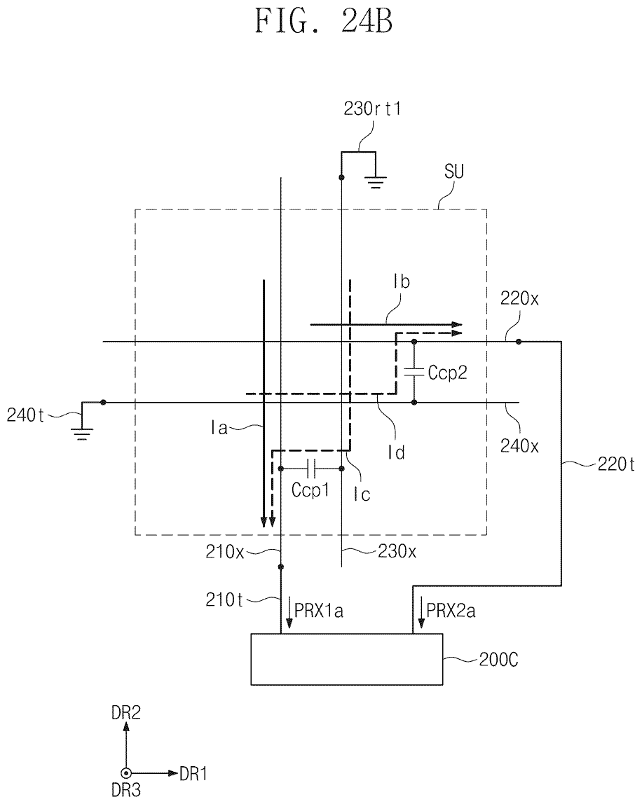

FIG. 24A is a diagram illustrating a second mode according to an embodiment of the present disclosure. FIG. 24B is a diagram illustrating a second mode based on one sensing unit SU according to an embodiment of the present disclosure.

Referring to FIGS. 24A and 24B, the second mode may include the charging driving mode and the pen sensing driving mode. FIGS. 24A and 24B are diagrams illustrating the pen sensing driving mode.

Referring to FIG. 24A, in the pen sensing driving mode, first reception signals PRX1 may be output from the first electrodes 210, and second reception signals PRX2 may be output from the second electrodes 220. One sensing unit SU in which first to fourth induced currents Ia, Ib, Ic, and Id generated by the pen PN is illustrated in FIG. 24B.

Referring to FIGS. 24A and 24B, in an embodiment of the present disclosure, the routing directions of one electrode of the sensor layer 200 and another electrode thereof, which overlap with each other, may be different from each other. For example, the routing direction of a first electrode 210x may be different from the routing direction of a third electrode 230x. Also, the routing direction of a second electrode 220x may be different from the routing direction of a fourth electrode 240x. For example, in FIG. 24B, the first electrode 210x and the first trace line 210t may be connected to each other in a lower portion of the sensing unit SU. The third electrode 230x and the first loop trace line 230rt1 may be connected to each other in an upper portion of the sensing unit SU. The second electrode 220x and the second trace line 220t may be connected to each other on the right side of the sensing unit SU. The fourth electrode 240x and the group trace line 240t may be connected to each other on the left side of the sensing unit SU.

The RLC resonant circuit of the pen PN may form a magnetic field of a resonant frequency while discharging the charged charges. Due to the magnetic field provided by the pen PN, the first induced current Ia may be generated in the first electrode 210x, and the second induced current Ib may be generated in the second electrode 220x. Moreover, the third induced current Ic may be generated in the third electrode 230x, and the fourth induced current Id may be generated in the fourth electrode 240x.

A first coupling capacitor Ccp1 may be formed between the third electrode 230x and the first electrode 210x. A second coupling capacitor Ccp2 may be formed between the fourth electrode 240x and the second electrode 220x. The third induced current Ic may be delivered to the first electrode 210x through the first coupling capacitor Ccp1. The fourth induced current Id may be delivered to the second electrode 220x through the second coupling capacitor Ccp2.

The sensor driver 200C may receive a first reception signal PRX1a, which is based on the first induced current Ia and the third induced current Ic, from the first electrode 210x, and may receive a second reception signal PRX2a, which is based on the second induced current Ib and the fourth induced current Id, from the second electrode 220x. The sensor driver 200C may detect input coordinates of the pen PN based on the first reception signal PRX1a and the second reception signal PRX2a.

The sensor driver 200C may receive the first reception signal PRX1a from the first electrode 210x, and may receive the second reception signal PRX2a from the second electrode 220x. In this case, all ends of the third electrode 230x and the fourth electrode 240x may be floated. Accordingly, the sensing signal may be maximally compensated for by the coupling between the first electrode 210x and the third electrode 230x, and the coupling between the second electrode 220x and the fourth electrode 240x.

The other ends of the third electrode 230x and the fourth electrode 240x may be grounded or floated. Accordingly, the third induced current Ic and the fourth induced current Id may be sufficiently delivered to the first electrode 210x and the second electrode 220x by the coupling between the first electrode 210x and the third electrode 230x, and by the coupling between the second electrode 220x and the fourth electrodes 240x.

As described above, the area of the sensing area may be wider than the area of the display area. Therefore, a part of the sensing area may overlap with the non-display area. In this case, even when an input occurs adjacent to a boundary between the display area and the non-display area, a signal may be sufficiently recognized, because the sensing area overlaps with a part of the non-display area. Therefore, an accuracy of coordinates of a touch input onto the outskirt of the display area may be improved.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic device comprising:
a display layer comprising a display area configured to display an image, and a non-display area adjacent to the display area; and
a sensor layer on the display layer, and comprising:
a plurality of first electrodes along a first direction;
a plurality of second electrodes along a second direction crossing the first direction;
a plurality of third electrodes along the first direction, and overlapping with the plurality of first electrodes; and
a plurality of fourth electrodes along the second direction, and overlapping with the plurality of second electrodes,
wherein at least a part of the plurality of first electrodes, the plurality of second electrodes, the plurality of third electrodes, and the plurality of fourth electrodes overlaps with the non-display area.

2. The electronic device of claim 1, wherein a length of each of the plurality of first electrodes in the second direction is larger than a width of the display area in the second direction.

3. The electronic device of claim 2, wherein each of the plurality of first electrodes comprises a first edge aligned with a boundary between the display area and the non-display area, and a second edge spaced from the first edge in the second direction.

4. The electronic device of claim 3, further comprising a plurality of pads electrically connected to the plurality of first electrodes, the plurality of second electrodes, the plurality of third electrodes, and the plurality of fourth electrodes,
wherein the first edge is located between the plurality of pads and the second edge.

5. The electronic device of claim 1, wherein at least a part of the plurality of first electrodes, the plurality of second electrodes, the plurality of third electrodes, and the plurality of fourth electrodes comprises an extended portion overlapping with the non-display area, and
wherein a plurality of openings are defined in the extended portion.

6. The electronic device of claim 5, wherein each of the plurality of openings has a circular shape.

7. The electronic device of claim 1, wherein the plurality of first electrodes comprises a plurality of first type electrodes in an area overlapping with the display area, and a second type electrode in an area overlapping with the non-display area.

8. The electronic device of claim 7, wherein each of the plurality of first type electrodes has a mesh structure in which a plurality of openings are defined, and the second type electrode has a solid structure in which no opening is defined.

9. The electronic device of claim 7, wherein the second type electrode has a loop shape.

10. The electronic device of claim 7, wherein the sensor layer further comprises:
a first loop trace line electrically connected to the plurality of third electrodes; and
a plurality of second loop trace lines electrically connected to the plurality of third electrodes, and
wherein the second type electrode is adjacent to the first loop trace line.

11. The electronic device of claim 10, wherein the first loop trace line is located between the second type electrode and the display layer.

12. The electronic device of claim 10, wherein one of the first loop trace line or the second type electrode comprises:
a first conductive line; and
a second conductive line at a different layer from that of the first conductive line, and electrically connected to the first conductive line.

13. The electronic device of claim 1, wherein the plurality of second electrodes comprises a plurality of first type electrodes in an area overlapping with the display area, and a second type electrode in an area overlapping with the non-display area.

14. The electronic device of claim 13, wherein the sensor layer further comprises:
a trace line electrically connected to the plurality of fourth electrodes;
an auxiliary electrode electrically connected to the trace line, and overlapping with the non-display area; and
an auxiliary trace line electrically connected to the second type electrode, and spaced from the trace line with the display area therebetween.

15. The electronic device of claim 1, further comprising a sensor driver configured to drive the sensor layer, and selectively operate in a first mode for sensing a touch input and a second mode for sensing a pen input,
wherein the second mode comprises a charging driving mode and a pen sensing driving mode,
wherein, in the charging driving mode, the sensor driver is configured to provide a first signal to at least one third electrode among the plurality of third electrodes, and provide a second signal to at least another third electrode among the plurality of third electrodes, and
wherein, in the pen sensing driving mode, the sensor driver is configured to receive first reception signals from the plurality of first electrodes, and receive second reception signals from the plurality of second electrodes.

16. An electronic device comprising:
a display layer comprising a display area configured to display an image, and a non-display area adjacent to the display area; and
a sensor layer on the display layer, and comprising:
a plurality of first electrodes along a first direction;
a plurality of second electrodes along a second direction crossing the first direction;
a plurality of third electrodes along the first direction, and overlapping with the plurality of first electrodes; and
a plurality of fourth electrodes along the second direction, and overlapping with the plurality of second electrodes, at least a part of the plurality of fourth electrodes being electrically connected to each other,
wherein at least a part of the plurality of first electrodes, the plurality of second electrodes, the plurality of third electrodes, and the plurality of fourth electrodes comprises an extended portion overlapping with the non-display area, and a plurality of openings are defined in the extended portion.

17. An electronic device comprising:
a display layer comprising a display area configured to display an image, and a non-display area adjacent to the display area; and
a sensor layer on the display layer, and comprising:
a plurality of first electrodes along a first direction; and
a plurality of second electrodes along a second direction crossing the first direction,
wherein the plurality of first electrodes comprises:
a plurality of first type electrodes in an area overlapping with the display area; and
a second type electrode in an area overlapping with the non-display area, and
wherein each of the plurality of first type electrodes has a mesh structure in which a plurality of openings are defined, and the second type electrode has a solid structure in which no opening is defined.

18. The electronic device of claim 17, further comprising:
a first pad connected to one end of the second type electrode; and
a second pad connected to another end of the second type electrode.

19. The electronic device of claim 17, wherein the plurality of second electrodes comprises:
a plurality of third type electrodes in an area overlapping with the display area; and
a fourth type electrode in an area overlapping with the non-display area.

20. The electronic device of claim 19, wherein the sensor layer further comprises:
a plurality of third electrodes along the second direction, and overlapping with the plurality of second electrodes;
a trace line electrically connected to the plurality of third electrodes;
an auxiliary electrode electrically connected to the trace line, and overlapping with the non-display area; and
an auxiliary trace line electrically connected to the fourth type electrode, and spaced from the trace line with the display area therebetween.
